(19) United States
(12) Patent Application Publication
(10) Pub. No.: US 2024/0407164 A1
(43) Pub. Date: Dec. 5, 2024

(54) THREE-DIMENSIONAL MEMORY DEVICES INCLUDING SELF-ALIGNED CHANNEL CAP STRUCTURES AND METHODS FOR FORMING THE SAME

(71) Applicant: WESTERN DIGITAL TECHNOLOGIES, INC., SAN JOSE, CA (US)

(72) Inventors: Naoto NORIZUKI, Yokkaichi (JP); Teruo OKINA, Yokkaichi (JP)

(21) Appl. No.: 18/450,095

(22) Filed: Aug. 15, 2023

Related U.S. Application Data
(60) Provisional application No. 63/504,915, filed on May 30, 2023.

(51) Int. Cl. H10B 43/27; H01L 23/00; H01L 25/00; H01L 25/065; H01L 25/18; H10B 41/27; H10B 41/35; H10B 43/35; H10B 80/00

(52) U.S. Cl. CPC H10B 43/27; H01L 24/08; H01L 24/80; H01L 25/0657; H01L 25/18; H01L 25/50; H10B 41/27; H10B 41/35; H10B 43/35; H10B 80/00; H01L 2224/08145; H01L 2224/80006; H01L 2224/80895; H01L 2224/80896; H01L 2924/1431; H01L 2924/14511

(57) ABSTRACT

A semiconductor structure includes an alternating stack of insulating layers and electrically conductive layers, a memory opening vertically extending through the alternating stack, a memory opening fill structure located in the memory opening and comprising a memory film, a vertical semiconductor channel, and a semiconductor cap structure that includes a semiconductor core structure contacting a bottom end of the vertical semiconductor channel and an annular semiconductor structure laterally surrounding the semiconductor core structure and having a lesser vertical extent than the semiconductor core structure, and a source layer contacting a bottom surface of the semiconductor core structure.

### FIELD

The present disclosure relates generally to the field of semiconductor devices, and particularly to three-dimensional memory devices including self-aligned channel cap structures and methods for forming the same.

### BACKGROUND

Three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a semiconductor structure is provided, which comprises: an alternating stack of insulating layers and electrically conductive layers; a memory opening vertically extending through the alternating stack; a memory opening fill structure located in the memory opening and comprising a memory film, a vertical semiconductor channel, and a semiconductor cap structure that includes a semiconductor core structure contacting a bottom end of the vertical semiconductor channel and an annular semiconductor structure laterally surrounding the semiconductor core structure and having a lesser vertical extent than the semiconductor core structure; and a source layer contacting a bottom surface of the semiconductor core structure.

According to another aspect of the present disclosure, a method of forming a semiconductor structure is provided. The method comprises: forming a material layer over a carrier substrate; forming an alternating stack of insulating layers and spacer material layers over the material layer, wherein the spacer material layers are formed as, or are subsequently replaced with, electrically conductive layers; forming a memory opening through the alternating stack and into the material layer; forming an annular cavity around a bottom portion of the memory opening at a level of the material layer; forming a memory film on exposed surfaces of the memory opening and the annular cavity; forming an annular semiconductor structure within a remaining volume of the annular cavity; forming a semiconductor core structure on an inner sidewall of the annular semiconductor structure; and forming a vertical semiconductor channel on a top surface of the semiconductor core structure.

### BRIEF DESCRIPTION OF THE DRAWINGS

FIG. 1 is a schematic vertical cross-sectional view of a first exemplary structure after formation of an insulating material layer, a semiconductor material layer, and a first-tier alternating stack of first insulating layers and first sacrificial material layers over a carrier substrate according to a first embodiment of the present disclosure.

FIG. 2 is a schematic vertical cross-sectional view of the first exemplary structure after formation of first stepped surfaces and a first stepped dielectric material portion according to the first embodiment of the present disclosure.

FIG. 3 is a schematic vertical cross-sectional view of the first exemplary structure after formation of first-tier openings according to the first embodiment of the present disclosure.

FIG. 4 is a vertical cross-sectional view of the first exemplary structure after formation of sacrificial opening fill structures according to the first embodiment of the present disclosure.

FIG. 5 is a vertical cross-sectional view of the first exemplary structure after formation of a second-tier alternating stack of second insulating layers and second sacrificial material layers, second stepped surfaces, and a second retro-stepped dielectric material portion according to the first embodiment of the present disclosure.

FIG. 6 is a vertical cross-sectional view of the first exemplary structure after formation of second-tier openings according to the first embodiment of the present disclosure.

FIG. 7A is a schematic vertical cross-sectional view of the first exemplary structure after formation of inter-tier memory openings and inter-tier support openings according to the first embodiment of the present disclosure.

FIG. 7B is a top-down view of the first exemplary structure of FIG. 7A. The vertical plane A-A is the cut plane of the vertical cross-sectional view of FIG. 7A.

FIGS. 8A-8G are sequential vertical cross-sectional views of a memory opening during formation of a memory opening fill structure in the first exemplary structure according to the first embodiment of the present disclosure.

FIG. 9A is a schematic vertical cross-sectional view of the first exemplary structure after formation of memory opening fill structures according to the first embodiment of the present disclosure.

FIG. 9B is a top-down view of the first exemplary structure of FIG. 9A. The vertical plane A-A is the cut plane of the vertical cross-sectional view of FIG. 9A.

FIG. 10A is a vertical cross-sectional view of the first exemplary structure after formation of lateral isolation trenches according to the first embodiment of the present disclosure.

FIG. 10B is a top-down view of the first exemplary structure of FIG. 10A. The vertical plane A-A is the cut plane of the vertical cross-sectional view of FIG. 10A.

FIG. 11 is a vertical cross-sectional view of the first exemplary structure after formation of laterally-extending cavities according to the first embodiment of the present disclosure.

FIG. 12 is a schematic vertical cross-sectional view of the first exemplary structure after formation of electrically conductive layers according to the first embodiment of the present disclosure.

FIG. 13A is a vertical cross-sectional view of the first exemplary structure after formation of lateral isolation trench fill structures, layer contact via structures, and drain contact via structures according to the first embodiment of the present disclosure.

FIG. 13B is a top-down view of the first exemplary structure of FIG. 13A. The vertical plane A-A is the cut plane of the vertical cross-sectional view of FIG. 13A.

FIG. 14 is a vertical cross-sectional view of the first exemplary structure after formation of a memory die according to the first embodiment of the present disclosure.

FIG. 15 is a vertical cross-sectional view of a logic die according to the first embodiment of the present disclosure.

FIG. 16 is a vertical cross-sectional view of the first exemplary structure after attaching the logic die to the memory die according to the first embodiment of the present disclosure.

FIG. 17 is a vertical cross-sectional view of the first exemplary structure after thinning of the carrier substrate according to the first embodiment of the present disclosure.

FIG. 18A is a vertical cross-sectional view of the first exemplary structure after removal of the carrier substrate and the insulating material layer according to the first embodiment of the present disclosure.

FIGS. 18B and 18C are magnified views of a region of alternative configurations of the first exemplary structure of FIG. 18A.

FIG. 19 is a vertical cross-sectional view of the first exemplary structure after formation of a source layer according to the first embodiment of the present disclosure.

FIG. 20A is a vertical cross-sectional view of the first exemplary structure after formation of a backside insulating layer and a source contact structure according to the first embodiment of the present disclosure.

FIGS. 20B and 20C are magnified views of a region of alternative configurations of the first exemplary structure of FIG. 20A.

FIG. 21 is a schematic vertical cross-sectional view of a second exemplary structure after formation of first-tier openings according to the second embodiment of the present disclosure.

FIG. 22 is a schematic vertical cross-sectional view of the second exemplary structure after formation of inter-tier memory openings and inter-tier support openings according to the second embodiment of the present disclosure.

FIGS. 23A-23G are sequential vertical cross-sectional views of a memory opening during formation of a memory opening fill structure in the second exemplary structure according to the second embodiment of the present disclosure.

FIGS. 24A-24C are sequential vertical cross-sectional views of a region of the second exemplary structure during removal of the carrier substrate, the insulating material layer, and bottom portions of the semiconductor material layer and memory openings, and formation of a source layer according to the second embodiment of the present disclosure.

FIG. 25A is a vertical cross-sectional view of a third exemplary structure after formation of sacrificial plate structures according to a third embodiment of the present disclosure.

FIG. 25B is a top-down view of the third exemplary structure of FIG. 25A.

FIG. 26 is a schematic vertical cross-sectional view of a third exemplary structure after formation of first-tier openings according to the third embodiment of the present disclosure.

FIG. 27 is a schematic vertical cross-sectional view of the third exemplary structure after formation of inter-tier memory openings and inter-tier support openings according to the third embodiment of the present disclosure.

FIGS. 28A-28G are sequential vertical cross-sectional views of a memory opening during formation of a memory opening fill structure in the third exemplary structure according to the third embodiment of the present disclosure.

FIGS. 29A-29C are sequential vertical cross-sectional views of a region of the third exemplary structure during removal of the carrier substrate and bottom portions of the buried insulating layer and memory openings, and formation of a source layer according to the third embodiment of the present disclosure.

FIG. 30 is a schematic vertical cross-sectional view of the third exemplary structure after formation of a source contact structure according to the third embodiment of the present disclosure.

### DETAILED DESCRIPTION

As discussed above, the embodiments of the present disclosure are directed to a three-dimensional memory device containing self-aligned channel cap structures and methods for forming the same, the various aspects of which are described below. Embodiments of the disclosure can be employed to form various structures including a multilevel memory structure, non-limiting examples of which include three-dimensional memory devices comprising a plurality of memory strings.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased in a single erase operation. Each block contains a number of pages, which are the smallest unit that can be programmed, i.e., a smallest unit on which a read operation can be performed.

As used herein, a “semiconducting material” refers to a material having electrical conductivity in the range from 1×10⁻⁵ S/m to 1×10⁵ S/m. As used herein, a “semiconductor material” refers to a material having electrical conductivity in the range from 1×10⁻⁵ S/m to 1 S/m in the absence of electrical dopants therein, and is capable of producing a doped material having electrical conductivity in a range from 1 S/m to 1×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1×10⁵ S/m. As used herein, an “insulator material” or a “dielectric material” refers to a material having electrical conductivity less than 1×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1×10⁻⁵ S/m to 1×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

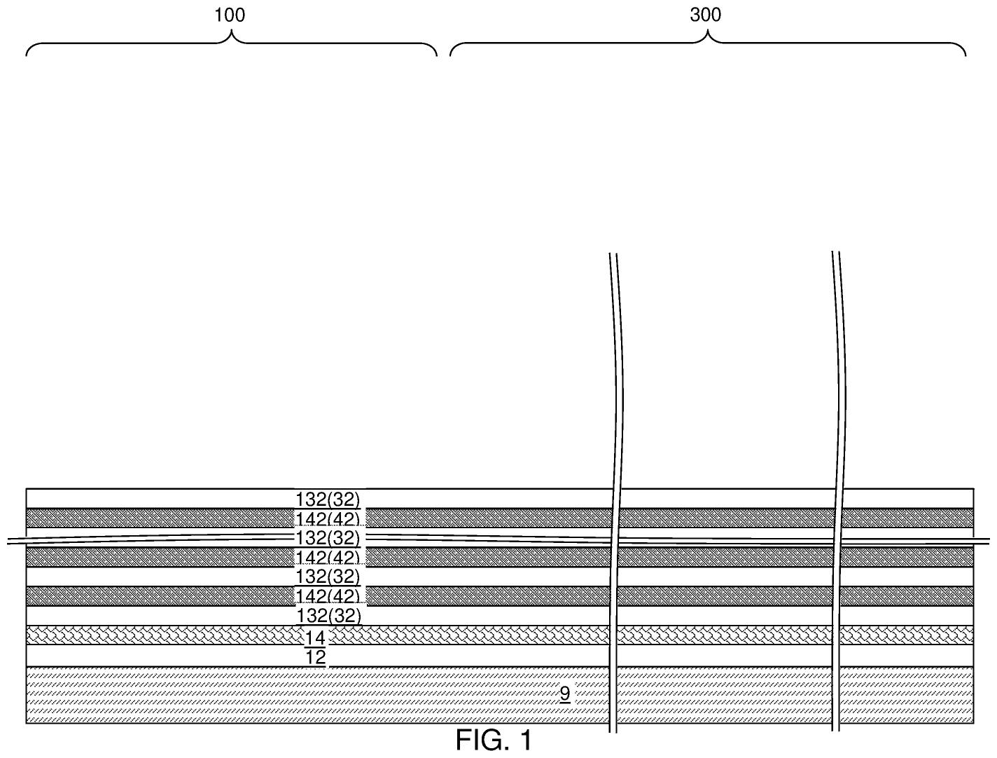

Referring to FIG. 1, a first exemplary structure according to a first embodiment of the present disclosure is illustrated. The first exemplary structure comprises a carrier substrate 9, which may be a semiconductor substrate or a conductive substrate. For example, the carrier substrate 9 may comprise a commercially available silicon wafer. Alternatively, the carrier substrate 9 may comprise any material that may be removed selective the materials of insulating layers 32 and dielectric material portions to be subsequently formed. In case the carrier substate 9 comprise silicon (e.g., a single crystal silicon wafer), at least a top surface portion of the carrier substrate 9 may be doped with boron to act as an etch stop and to prevent collateral etching during a subsequent etching step. The atomic concentration of boron in at least the boron-doped portion of the carrier substrate 9 (or in the entire carrier substrate) may be at least 1×10¹⁹/cm³, such as in a range from 5×10¹⁹/cm³ to 2×10²¹/cm³, such as from 1×10²⁰/cm³ to 1×10²¹/cm³, although lesser and greater thicknesses may also be employed.

A buried insulating layer 12 can be formed on the top surface of the carrier substrate 9. The buried insulating layer 12 comprises an insulating material, such as silicon oxide, and may have a thickness in a range from 10 nm to 200 nm, such as from 20 nm to 100 nm, although lesser and greater thicknesses may also be employed. The buried insulating layer 12 may be deposited on the carrier substrate 9 by chemical vapor deposition, atomic layer deposition or sputtering. Alternatively, if the carrier substrate 9 comprises a silicon substrate, then the buried insulating layer 12 may be formed by oxidizing an upper surface of the carrier substrate 9.

A semiconductor material layer 14 can be formed over the buried insulating layer 12. The semiconductor material layer 14 comprises and/or consists essentially of a semiconductor material, which may be an elemental semiconductor material such as silicon or germanium, or a compound semiconductor material such as silicon-germanium or a III-V compound semiconductor material. If the carrier substrate 9 comprises a semiconductor material, the semiconductor material layer 14 may comprise a semiconductor material providing a higher etch rate than the semiconductor material of the carrier substrate 9 during an isotropic etch process.

For example, if the carrier substrate 9 comprises boron doped silicon, the semiconductor material layer 14 may comprise undoped (i.e., intrinsic) silicon. In one embodiment, the atomic concentration of electrical dopants (such residual p-type dopants or n-type dopants) in the semiconductor material layer 14 may be less than 5×10¹⁵/cm³, such as in a range from 1×10¹¹/cm³ to 1×10¹⁵/cm³, such as from 1×10¹²/cm³ to 1×10¹⁴/cm³. Alternatively, if the carrier substrate 9 comprises undoped silicon, the semiconductor material layer 14 may comprise a silicon-germanium compound semiconductor material including germanium at an atomic concentration greater than 10%, which can be etched at a higher etch rate than silicon in buffered hydrofluoric acid or in a mixture of a nitric acid and hydrofluoric acid.

The thickness of the semiconductor material layer 14 is less than the lateral dimension (such as the diameter) of memory openings to be subsequently formed, and is greater than twice the thickness of memory films to be subsequently formed therein. In one embodiment, the thickness of the semiconductor material layers 14 may be in a range from 20 nm to 60 nm, such as from 35 nm to 50 nm, although lesser and greater thicknesses may also be employed.

A first alternating stack of insulating layers 32 and spacer material layers can be formed over the carrier substrate 9. The spacer material layers may be formed as sacrificial material layers 42. In case a second alternating stack of additional insulating layers and additional spacer material layers is subsequently formed over the first alternating stack to form a multi-tier structure, the first alternating stack is referred to as a first-tier alternating stack, and the second alternating stack is referred to as a second-tier alternating stack. FIG. 1 illustrates the first-tier alternating stack, and does not illustrate a second-tier alternating stack. In this case, the insulating layers 32 within the first-tier alternating stack are herein referred to as first insulating layers 132, and spacer material layers (such as the sacrificial material layers 42) within the first-tier alternating stack are herein referred to as first spacer material layers (such as first sacrificial material layers 142). In one embodiment, the first spacer material layers may comprise first sacrificial material layers 142. In this case, a first-tier alternating stack (132, 142) of first insulating layers 132 and first sacrificial material layers 142 can be formed over the semiconductor material layer 14.

The first insulating layers 132 comprise an insulating material such as undoped silicate glass or a doped silicate glass, and the first sacrificial material layers 142 comprise a sacrificial material such as silicon nitride or a silicon-germanium alloy. In one embodiment, the first insulating layers 132 may comprise silicon oxide layers, and the first sacrificial material layers 142 may comprise silicon nitride layers. The first-tier alternating stack (132, 142) may comprise multiple repetitions of a unit layer stack including a first insulating layer 132 and a first sacrificial material layer 142. The total number of repetitions of the unit layer stack within the first-tier alternating stack (132, 142) may be, for example, in a range from 8 to 1,024, such as from 32 to 256, although lesser and greater number of repetitions may also be employed.

Each of the first insulating layers 132 may have a thickness in a range from 20 nm to 100 nm, such as from 30 nm to 60 nm, although lesser and greater thicknesses may also be employed. Each of the first sacrificial material layers 142 may have a thickness in a range from 20 nm to 100 nm, such as from 30 nm to 60 nm, although lesser and greater thicknesses may also be employed. The first exemplary structure comprises a memory array region 100 in which a three-dimensional array of memory elements is to be subsequently formed, and a contact region 300 in which layer contact via structures contacting word lines are to be subsequently formed.

While an embodiment is described in which the first spacer material layers are formed as first sacrificial material layers 142, the first spacer material layers may be formed as first electrically conductive layers in an alternative embodiment. In this case, processing steps performed to replace the first sacrificial material layers 142 with first electrically conductive layers may be omitted. Generally, spacer material layers of the present disclosure may be formed as, or may be subsequently replaced with, electrically conductive layers.

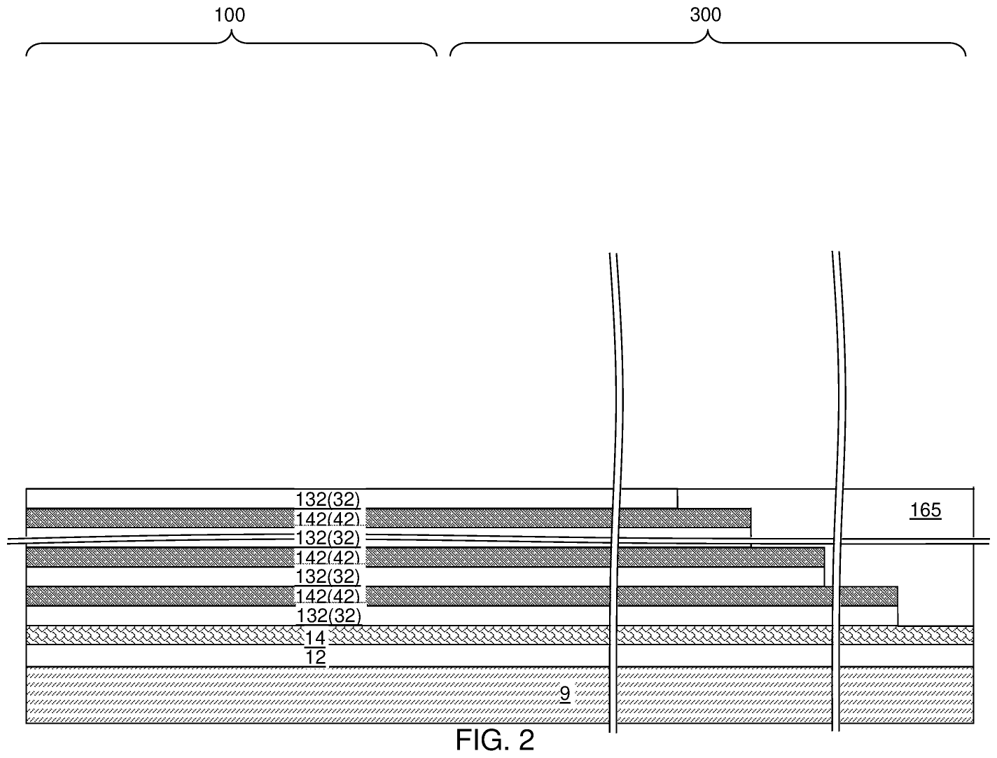

Referring to FIG. 2, optional stepped surfaces are formed in the contact region 300. As used herein, “stepped surfaces” refer to a set of surfaces that include at least two horizontal surfaces and at least two vertical surfaces such that each horizontal surface is adjoined to a first vertical surface that extends upward from a first edge of the horizontal surface, and is adjoined to a second vertical surface that extends downward from a second edge of the horizontal surface. A first stepped cavity is formed within the volume from which portions of the first-tier alternating stack (132, 142) are removed through formation of the stepped surfaces. A “stepped cavity” refers to a cavity having stepped surfaces.

The first stepped cavity can have various stepped surfaces such that the horizontal cross-sectional shape of the first stepped cavity changes in steps as a function of the vertical distance from the top surface of the carrier substrate 9. In one embodiment, the first stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

The stepped surfaces of the first-tier alternating stack (132, 142) continuously extend from a bottommost layer within the first-tier alternating stack (132, 142) to a topmost layer within the first-tier alternating stack (132, 142).

A first stepped dielectric material portion 165 (i.e., an insulating fill material portion) can be formed in the first stepped cavity by deposition of a dielectric material therein. For example, a dielectric material such as silicon oxide can be deposited in the stepped cavity. Excess portions of the deposited dielectric material can be removed from above the top surface of the topmost layer of the first-tier alternating stack (132, 142), for example, by chemical mechanical planarization (CMP). The remaining portion of the deposited dielectric material filling the first stepped cavity constitutes the first stepped dielectric material portion 165. As used herein, a “stepped” element refers to an element that has stepped surfaces and a horizontal cross-sectional area that increases or decreases stepwise as a function of a vertical distance from a top surface of a substrate on which the element is present. If silicon oxide is employed for the first stepped dielectric material portion 165, the silicon oxide of the first stepped dielectric material portion 165 may, or may not, be doped with dopants such as B, P, and/or F.

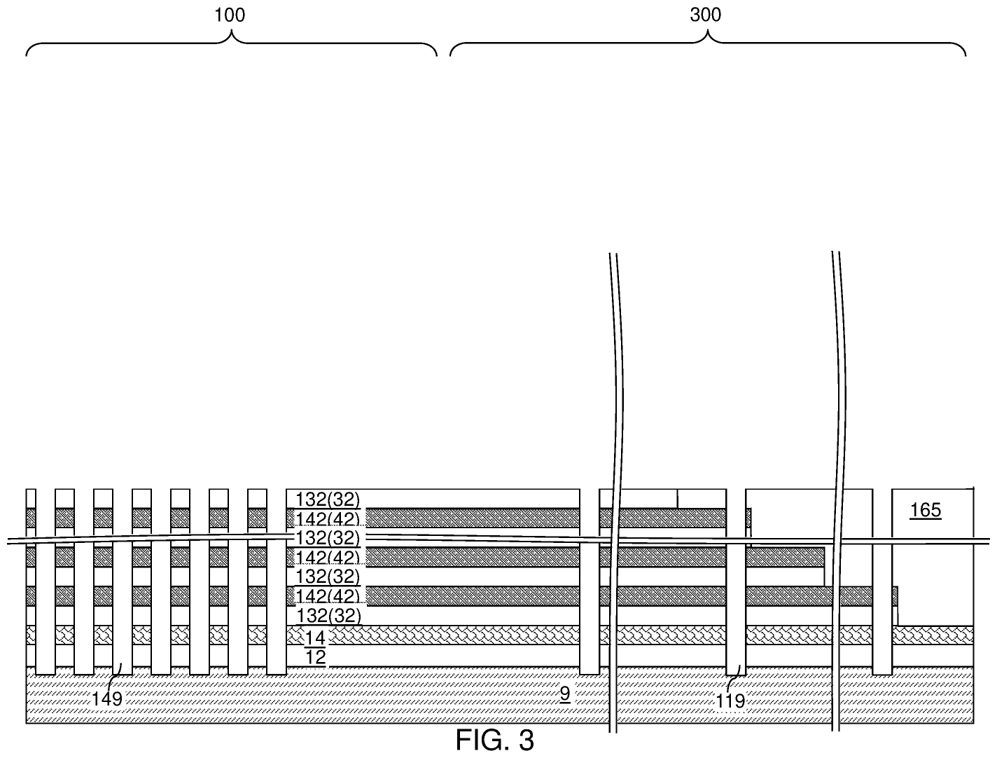

Referring to FIG. 3, a first etch mask layer (such as a photoresist layer) can be formed over the first-tier alternating stack (132, 142), and can be lithographically patterned to form openings therein. A first anisotropic etch process can be performed to transfer the pattern of the openings in the first etch mask layer through the first stepped dielectric material portion 165, the first-tier alternating stack (132, 142), the semiconductor material layer 14, and the buried insulating layer 12, and optionally into an upper portion of the carrier substrate 9. First-tier memory openings 149 can be formed through the first-tier alternating stack (132, 142) and the semiconductor material layer 14 in the memory array region 100, and first-tier support openings 119 can be formed through the first stepped dielectric material portion 165, the first-tier alternating stack (132, 142), and the semiconductor material layer 14 in the contact region 300. Each of the first-tier memory openings 149 and the first-tier support openings 119 can vertically extend into the carrier substrate 9. In one embodiment, bottom surfaces of the first-tier memory openings 149 and the first-tier support openings 119 may be formed at or below the top surface of the carrier substrate 9. The first-tier memory openings 149 and the first-tier support openings 119 may have a diameter in a range from 40 nm to 400 nm, such as from 80 nm to 200 nm, although lesser and greater thicknesses may be employed. The first etch mask layer can be removed, for example, by ashing after the first anisotropic etch process.

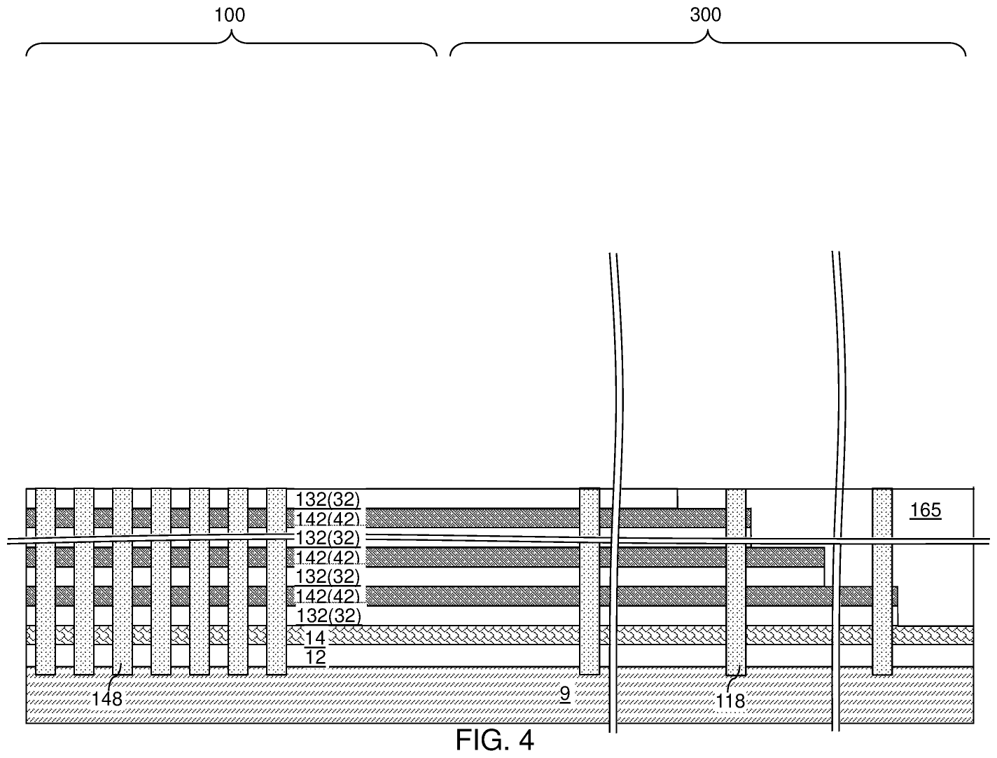

Referring to FIG. 4, a sacrificial fill material, such as a carbon-based material (e.g., amorphous carbon, diamond-like carbon, or a doped carbon material), a high etch-rate dielectric material (e.g., borosilicate glass or organosilicate glass), or a polymer material, can be deposited in the first-tier memory openings 149 and in the first-tier support openings 119 by a conformal deposition process. Excess portions of the sacrificial fill material can be removed from above the top surface of the first-tier alternating stack (132, 142), for example, by a recess etch process. Each remaining portion of the sacrificial fill material that fills a respective first-tier memory opening 149 constitutes a sacrificial memory opening fill structure 148. Each remaining portion of the sacrificial fill material that fills a respective first-tier support opening 119 constitutes a sacrificial support opening fill structure 118.

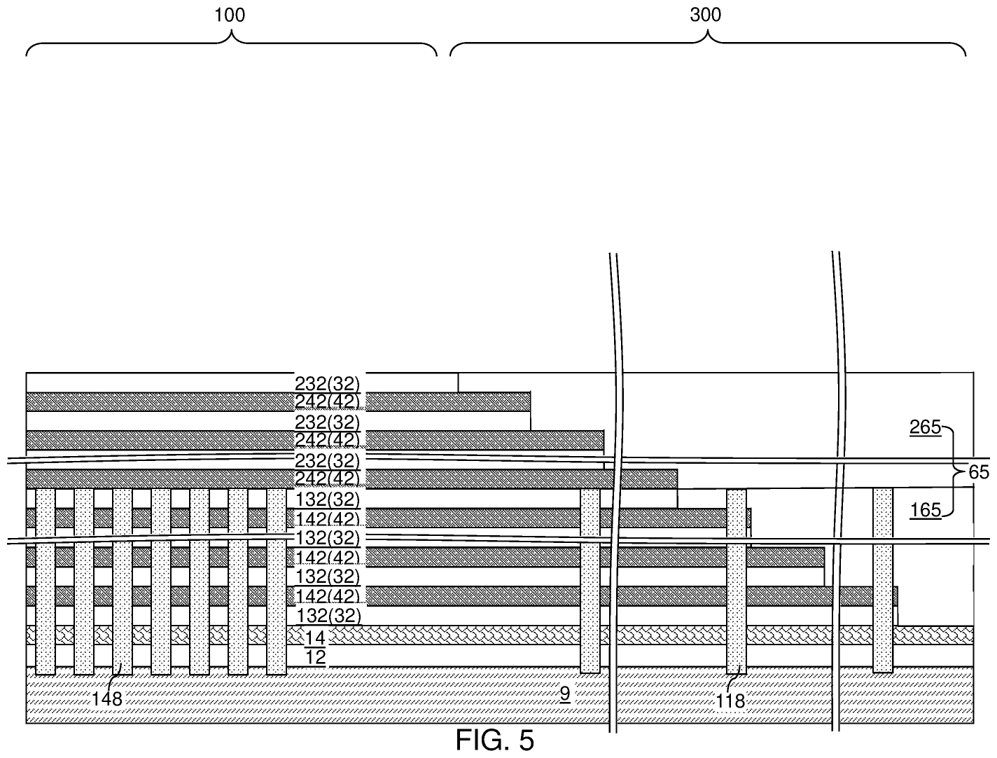

Referring to FIG. 5, a second-tier alternating stack (232, 242) of second insulating layers 232 and second spacer material layers may be formed above the first-tier alternating stack (132, 142) and the first stepped dielectric material portion 165. The second insulating layers 232 can be additional insulating layers 32 having a same material composition and a same thickness range as the first insulating layers 132. The second spacer material layers can be additional spacer material layers having a same material composition and a same thickness range as the first spacer material layers in the first-tier alternating stack (132, 142). In one embodiment, the second spacer material layers may comprise second sacrificial material layers 242. In this case, the second sacrificial material layers 242 can be additional sacrificial material layers 42 having a same material composition and a same thickness range as the first sacrificial material layers 142.

The second-tier alternating stack (232, 242) may comprise multiple repetitions of a unit layer stack including a second insulating layer 232 and a second sacrificial material layer 242. The total number of repetitions of the unit layer stack within the second-tier alternating stack (232, 242) may be, for example, in a range from 8 to 1,024, such as from 32 to 256, although lesser and greater number of repetitions may also be employed. Each of the second insulating layers 232 may have a thickness in a range from 20 nm to 100 nm, such as from 30 nm to 60 nm, although lesser and greater thicknesses may also be employed. Each of the second sacrificial material layers 242 may have a thickness in a range from 20 nm to 100 nm, such as from 30 nm to 60 nm, although lesser and greater thicknesses may also be employed.

While an embodiment is described in which the second spacer material layers are formed as second sacrificial material layers 242, the second spacer material layers may be formed as second electrically conductive layers in an alternative embodiment. In this case, processing steps performed to replace the second sacrificial material layers 242 with second electrically conductive layers may be omitted. Generally, spacer material layers of the present disclosure may be formed as, or may be subsequently replaced with, electrically conductive layers.

Optional stepped surfaces are formed in the contact region 300 by patterning the second-tier alternating stack (232, 242). The stepped surfaces of the second-tier alternating stack (232, 242) may be laterally offset toward the memory array region 100 relative to the stepped surfaces of the first-tier alternating stack (132, 142) in a plan view. A second stepped cavity is formed within the volume from which portions of the second-tier alternating stack (232, 242) are removed through formation of the stepped surfaces. A “stepped cavity” refers to a cavity having stepped surfaces. The second stepped cavity can have various stepped surfaces such that the horizontal cross-sectional shape of the second stepped cavity changes in steps as a function of the vertical distance from the top surface of the carrier substrate 9. In one embodiment, the second stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type.

The stepped surfaces of the second-tier alternating stack (232, 242) continuously extend from a bottommost layer within the second-tier alternating stack (232, 242) to a topmost layer within the second-tier alternating stack (232, 242).

A second stepped dielectric material portion 265 (i.e., an insulating fill material portion) can be formed in the second stepped cavity by deposition of a dielectric material therein. For example, a dielectric material such as silicon oxide can be deposited in the stepped cavity. Excess portions of the deposited dielectric material can be removed from above the top surface of the topmost layer of the second-tier alternating stack (232, 242), for example, by chemical mechanical planarization (CMP). The remaining portion of the deposited dielectric material filling the second stepped cavity constitutes the second stepped dielectric material portion 265. If silicon oxide is employed for the second stepped dielectric material portion 265, the silicon oxide of the second stepped dielectric material portion 265 may, or may not, be doped with dopants such as B, P, and/or F. The combination of the first stepped dielectric material portion 165 and the second stepped dielectric material portion 265 may be collectively referred to as a retro-stepped dielectric material portion 65.

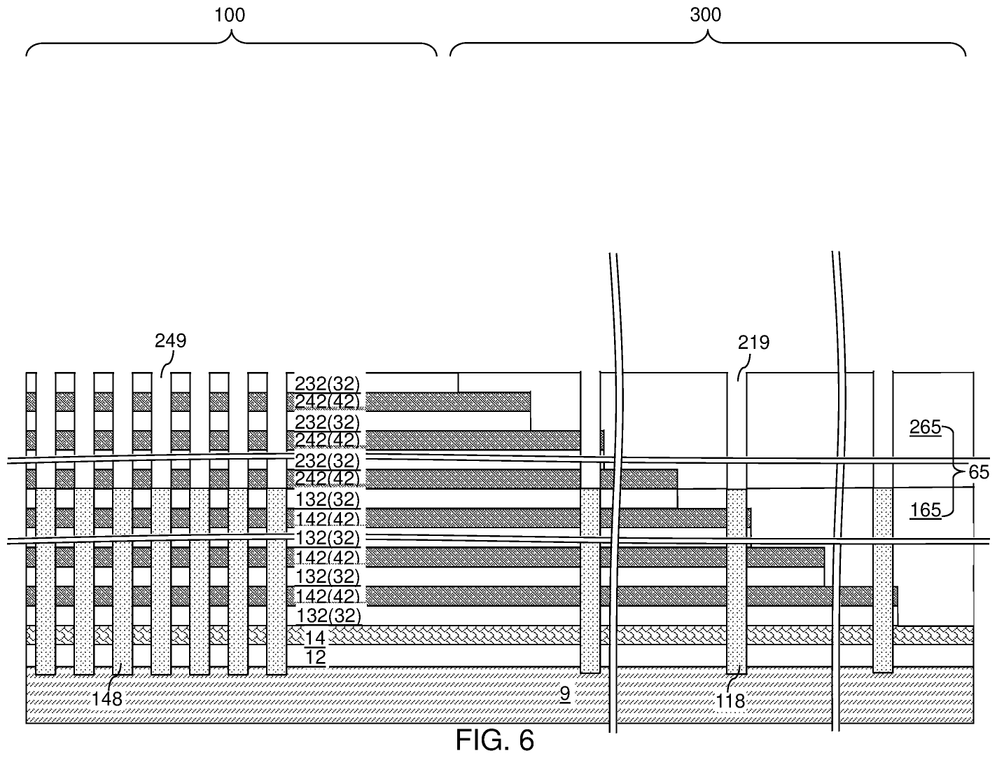

Referring to FIG. 6, a second etch mask layer (such as a photoresist layer) can be formed over the second-tier alternating stack (232, 242), and can be lithographically patterned to form openings therein. A second anisotropic etch process can be performed to transfer the pattern of the openings in the second etch mask layer through the second stepped dielectric material portion 265 and the second-tier alternating stack (232, 242). Second-tier memory openings 249 can be formed through the second-tier alternating stack (232, 242) directly on a top surface of a respective sacrificial memory opening fill structure 148 in the memory array region 100. Second-tier support openings 219 can be formed through the second stepped dielectric material portion 265 and the second-tier alternating stack (232, 242) directly on a top surface of a respective sacrificial support opening fill structure 118 in the contact region 300. Each of the second-tier memory openings 249 and the second-tier support openings 219 may have about the same diameter as the diameter of a respective underlying sacrificial opening fill structure (148, 118). The second etch mask layer can be removed, for example, by ashing after the second anisotropic etch process.

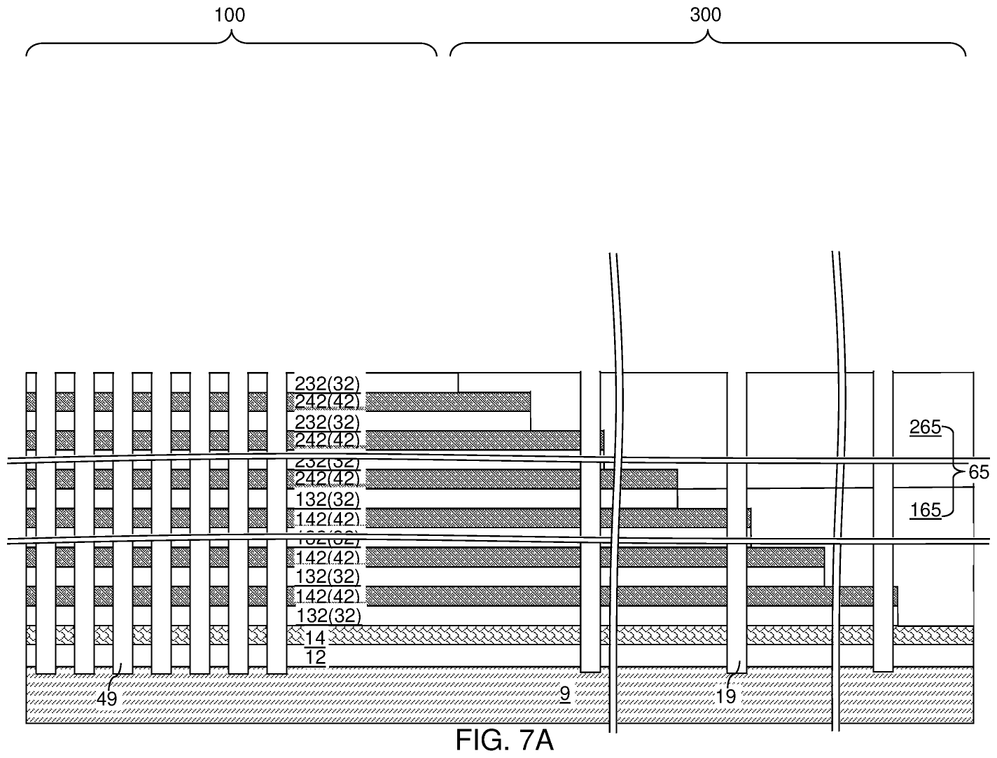

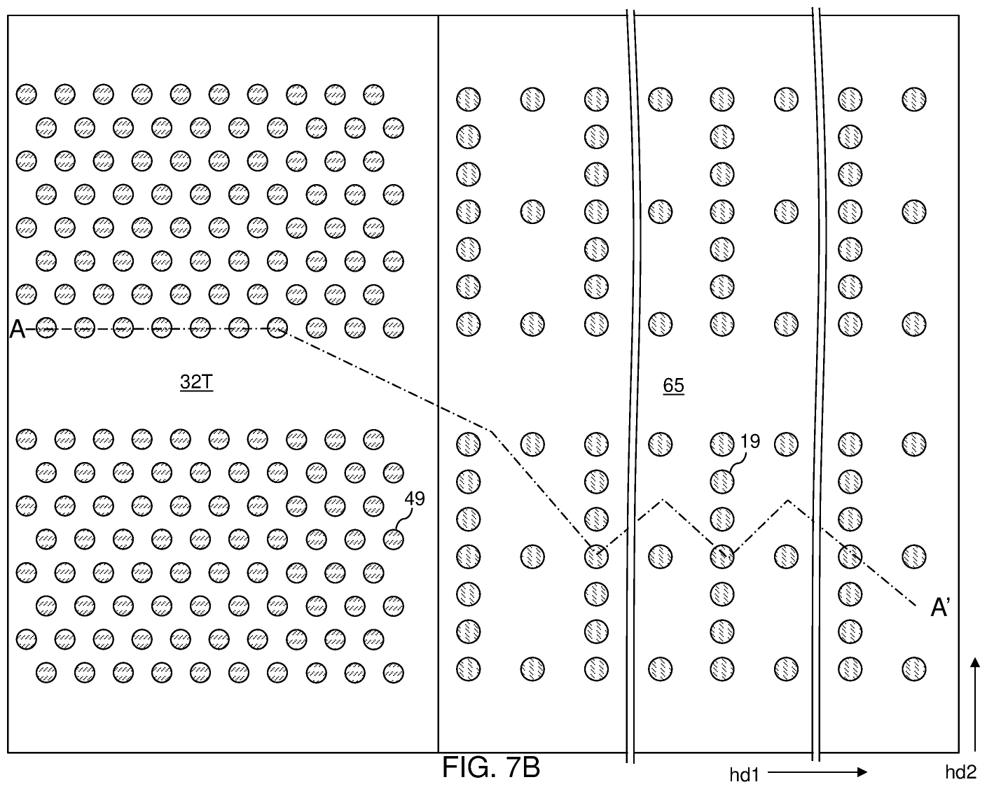

Referring to FIGS. 7A and 7B, the sacrificial memory opening fill structures 148 and the sacrificial support opening fill structures 118 may be removed selective to the materials of the second-tier alternating stack (232, 242), the first-tier alternating stack (132, 142), the stepped dielectric material portion 65, the semiconductor material layer 14, the buried insulating layer 12, and the carrier substrate 9. In an illustrative example, if the sacrificial memory opening fill structures 148 and the sacrificial support opening fill structures 118 comprise a carbon-based material, an ashing process may be performed to remove the sacrificial memory opening fill structures 148 and the sacrificial support opening fill structures 118. Inter-tier memory openings 49 (which are also referred to as memory openings 49) can be formed through the second-tier alternating stack (232, 242), the first-tier alternating stack (132, 142), the semiconductor material layer 14, and the buried insulating layer 12, and optionally into an upper portion of the carrier substrate 9. Inter-tier support openings 19 (which are also referred to as support openings 19) can be formed through the stepped dielectric material portion 65, at least through the first-tier alternating stack (132, 142) and optionally through the second-tier alternating stack (232, 242), and through the semiconductor material layer 14 and the buried insulating layer 12, and optionally into an upper portion of the carrier substrate 9.

In summary, a semiconductor material layer 14 can be formed over a carrier substrate 9, and at least one alternating stack of insulating layers 32 and spacer material layers (such as sacrificial material layers 42) may be formed over the semiconductor material layer 14 in the first exemplary structure. The spacer material layers are formed as, or are subsequently replaced with (if formed as sacrificial material layers 42), electrically conductive layers. Memory openings 49 can be formed through the alternating stack (32, 42) in the memory array region 100. The alternating stack (32, 42) may comprise a single-tier structure including a single stepped dielectric material portion, or may comprise a multi-tier structure including a first-tier alternating stack (132, 142) and a first stepped dielectric material portion 165 as a first-tier structure, and a second-tier alternating stack (232, 242) and a second stepped dielectric material portion 265 as a second-tier structure, and optionally including additional tier structures (not shown) that are formed above the second-tier structure.

Each of the memory openings 49 can vertically extend at least to a top surface of the carrier substrate 9. In one embodiment, bottom surfaces of the memory openings 49 may be formed at or below the top surface of the carrier substrate 9. Each cluster of memory openings 49 may comprise a plurality of rows of memory openings 49. Each row of memory openings 49 may comprise a plurality of memory openings 49 that are arranged along the first horizontal direction hd1 with a uniform pitch. The rows of memory openings 49 may be laterally spaced among one another along the second horizontal direction hd2, which may be perpendicular to the first horizontal direction hd2. In one embodiment, each cluster of memory openings 49 may be formed as a two-dimensional periodic array of memory openings 49. The memory openings 49 may have a diameter in a range from 60 nm to 400 nm, such as from 120 nm to 300 nm, although lesser and greater thicknesses may be employed. In the alternative embodiment, the support openings 19 are formed at the same time as the memory openings 49 using the same patterned photoresist layer.

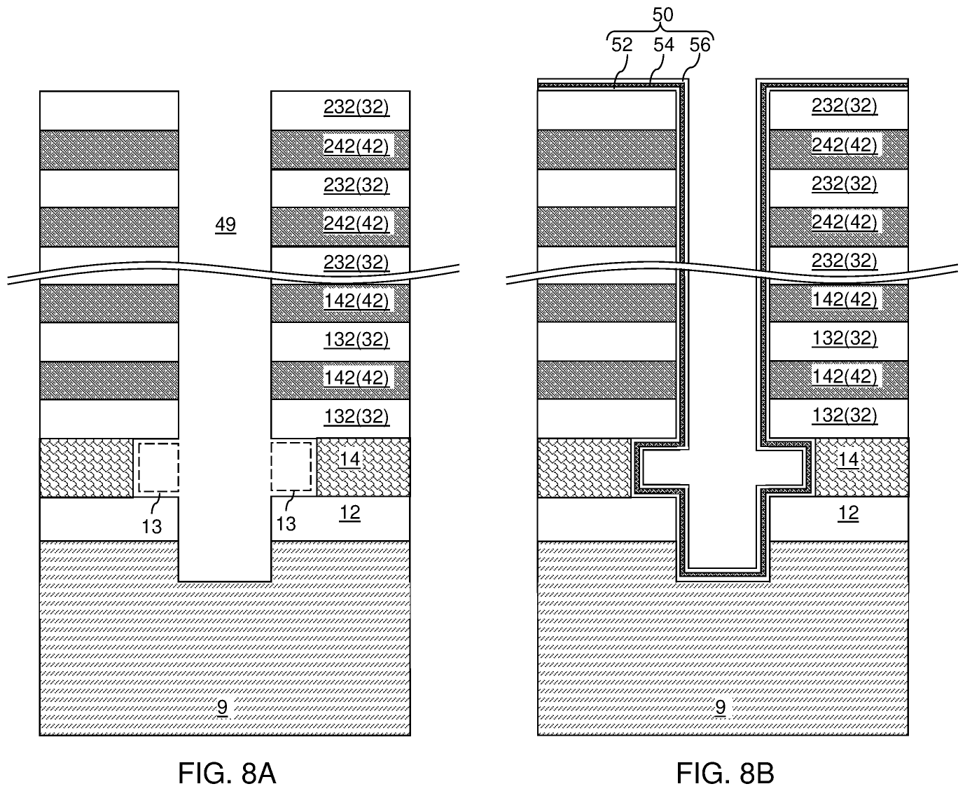

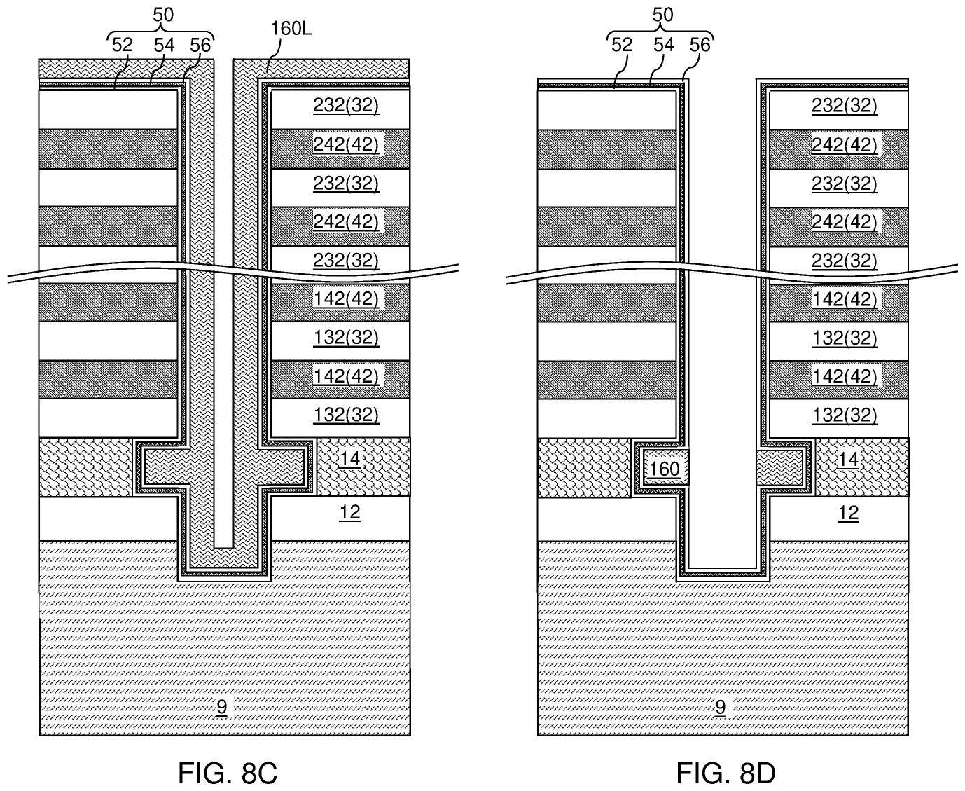

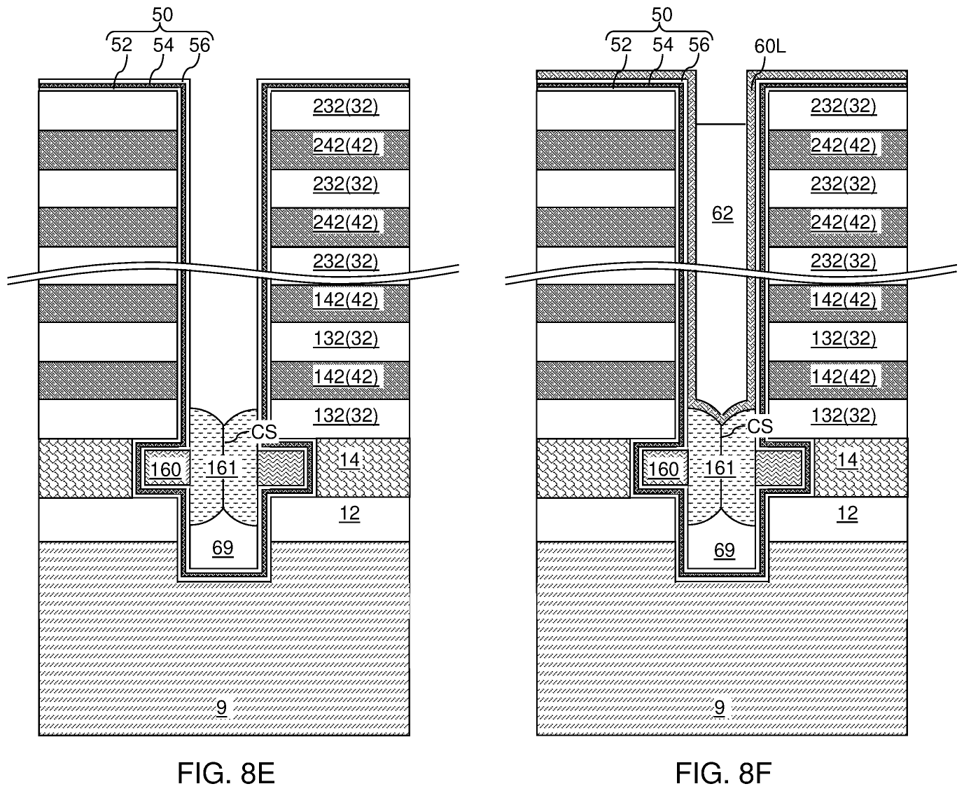

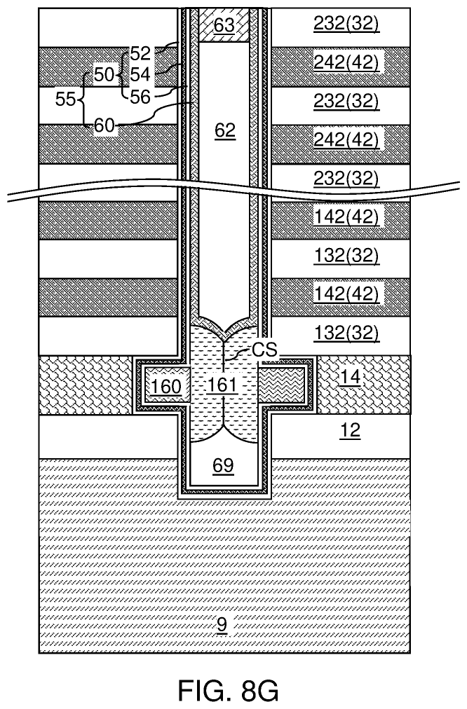

FIGS. 8A-8G are sequential vertical cross-sectional views of a memory opening 49 during formation of a memory opening fill structure 58 in the first exemplary structure according to the first embodiment of the present disclosure. A similar structural change may occur in every other memory opening 49 and in each of the support openings 19 during the processing steps of FIGS. 8A-8G.

Referring to FIG. 8A, an isotropic etch process, such as a selective wet etch process, may be performed, which etches the material of the semiconductor material layer 14 selective to the material of the physically exposed portion of the carrier substrate 9 that underlies the memory openings 49 and the support openings 19. As used herein, an etch process etches a first material selective to a second material if the etch rate of the etch process for the first material is at least three times the etch rate for the second material. In some embodiments, the etch rate of the isotropic etch process for the material of the semiconductor material layer 14 may be at least 5 times, and/or at least 10 times, the etch rate for the material of the carrier substrate 9.

For example, if the semiconductor material layer 14 comprises an undoped semiconductor material (such as undoped polysilicon or undoped amorphous silicon), and if at least the upper portion of the carrier substate 9 comprises boron-doped silicon, then the isotropic etch process may comprise an NC2 wet etch process, which is a wet etch process employing a mixture of nitric acid and hydrofluoric acid and etches undoped silicon selective to heavily boron-doped silicon. In another embodiment, if the carrier substrate 9 comprises doped or undoped silicon, and if the semiconductor material layer 14 comprises a silicon-germanium alloy including germanium at an atomic concentration greater than 10%, then a wet etch process employing buffered hydrofluoric acid or a mixture of a nitric acid and hydrofluoric acid may be employed for the isotropic etch process. Alternatively, an alkaline solution such as KOH may be employed to perform the isotropic etch process.

The isotropic etch process isotropically recesses the physically exposed cylindrical sidewalls of the semiconductor material layer 14 isotropically to form annular cavities 13 around each memory opening 49 and around each support opening 19. The lateral recess distance of the semiconductor material layer 14 of the isotropic etch process may be less than one half of the lateral spacing between neighboring pairs of memory openings 49, and is less than one half of the lateral spacing between neighboring pairs of support openings 19.

In summary, an annular cavity 13 can be formed around a bottom portion of each memory opening 49 at a level of the semiconductor material layer 14. In one embodiment, each annular cavity 13 may be formed by laterally recessing an annular portion of the semiconductor material layer 14 around a respective memory opening 49.

Referring to FIG. 8B, a memory film 50 including a memory material layer 54 can be conformally deposited. In an illustrative example, the memory film 50 may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride), a ferroelectric material, a phase change memory material, or any other memory material that can store data bits by inducing a change in the electrical resistivity, ferroelectric polarization, or any other measurable physical property. In case the memory material layer 54 comprises a charge storage material, the optional dielectric liner 56 may comprise a tunneling dielectric layer. The memory film 50 is formed on exposed surfaces of the memory openings 49 and the annular cavities 13.

Referring to FIG. 8C, a conformal semiconductor deposition process can be performed to deposit a semiconductor fill material in the annular cavity 13 and in a peripheral portion each memory opening 49. The deposited semiconductor fill material forms a semiconductor fill material layer 160L. The semiconductor fill material layer 160L may comprise an undoped semiconductor material (i.e., a semiconductor material, such as silicon, that does not include any intentionally introduced electrical dopants), or a doped semiconductor material, such as phosphorus doped silicon, having a doping of a conductivity type which is the opposite of the conductivity type of vertical semiconductor channels to be subsequently formed. For example, if the vertical semiconductor channels to be subsequently formed has a doping of a first conductivity type, the semiconductor fill material layer 160L may be undoped or has a doping of a second conductivity type that is the opposite of the first conductivity type. If the first conductivity type is p-type, the second conductivity type is n-type, and vice versa. If the semiconductor fill material layer 160L has a doping of the second conductivity type, the atomic concentration of dopants of the second conductivity type in the semiconductor fill material layer 160L may be in a range from 1×10¹⁴/cm³ to 1×10²¹/cm³, such as from 1×10¹⁶/cm³ to 1×10²⁰/cm³, although lesser and greater atomic concentrations may also be employed. The thickness of the semiconductor fill material layer 160L may be less than one half of the diameter of each memory opening 49 and may be less than one half of the diameter of each support opening 19. In this case, a cavity may be present within each memory opening 49 and within each support opening 19.

Referring to FIG. 8D, at least one etch process may be performed to remove portions of the semiconductor fill material layer 160L located outside the annular cavity 13. The at least one etch process may comprise an anisotropic etch process (such as a reactive ion etch process or a chemical dry etch process). Each remaining portion of the semiconductor fill material layer 160L that fills a volume of a respective annular cavity 13 constitutes an annular semiconductor structure 160, such as an annular silicon structure. In one embodiment, the anisotropic etch process removes portions of the semiconductor fill material layer 160L that are proximal to vertical sidewalls of the memory film 50. In this case, each annular semiconductor structure 160 may comprise a respective inner cylindrical sidewall that is vertically coincident with an inner sidewall of a memory film 50. As used herein, a first surface and a second surface are vertically coincident with each other if the second surface overlies or underlies the first surface and if there exists a vertical plane that contains the first surface and the second surface.

Referring to FIG. 8E, a selective semiconductor deposition process can be performed to grow a doped semiconductor material from physically exposed cylindrical surfaces of the annular semiconductor structures 160 while suppressing growth of the doped semiconductor material from physically exposed dielectric surfaces, such as the physically exposed surfaces of the memory film 50, e.g., from the physically exposed surfaces of the dielectric liner 56 (which may be a tunneling dielectric layer). A selective deposition process refers to a deposition process in which a material is grown from a first-type surface while deposition of the material from a second-type surface is suppressed. A selective semiconductor deposition process refers to a deposition process in which a semiconductor material (e.g., silicon) is grown from a first-type surface such as a physically exposed semiconductor (e.g., silicon) surface while deposition of the semiconductor material from a second-type surface, such as an insulating surface is suppressed.

The selective semiconductor deposition process forms a semiconductor core structure 161, such as a n-type (e.g., phosphorus) doped silicon core structure, on an inner sidewall of each annular semiconductor structure 160. The duration of the selective semiconductor deposition process can be selected such that growth surfaces of the semiconductor material of the semiconductor core structure 161 merge at a center portion to form a center seam CS.

According to an aspect of the present disclosure, the selective semiconductor deposition process may be performed with in-situ doping with dopants (e.g., phosphorus) of the second conductivity type (e.g., n-type). The atomic concentration of dopants of the second conductivity type in the semiconductor core structures 161 may be at least 1×10¹⁹/cm³, such as in a range from 5×10¹⁹/cm³ to 2×10²¹/cm³, such as from 1×10²⁰/cm³ to 1×10²¹/cm³, although lesser and greater atomic concentrations may also be employed. In an illustrative example, if the vertical semiconductor channels to be subsequently formed comprise silicon doped with p-type dopants (such as boron), then the semiconductor core structures 161 comprise silicon doped with n-type dopants (such as phosphorus or arsenic). The semiconductor core structures 161 form p-n junctions with respect to vertical semiconductor channels to be subsequently formed, and thus, function as components of source structures to be subsequently formed. Control of the duration of the selective semiconductor deposition process allows control of the location of the top surfaces of the semiconductor core structures 161, and thus, allows control of the height of the p-n junctions to be subsequently formed.

In one embodiment, each semiconductor core structure 161 may comprise a center seam CS that vertically extends from a center of a top surface thereof to a center of a bottom surface thereof. In one embodiment, each semiconductor core structure 161 comprises a contoured top surface having a periphery that is raised above a center point (located above the center seam) of the contoured top surface. In one embodiment, the contoured top surface of each semiconductor core structure 161 comprises two convex surfaces which meet at the center. In one embodiment, each semiconductor core structure 161 protrudes downward below a horizontal plane including a bottom surface of the annular semiconductor structure 160. In one embodiment, the semiconductor core structure 161 comprises a contoured bottom surface having a periphery that is located below a center point of the contoured bottom surface.

In one embodiment, each semiconductor core structure 161 comprises a contoured top surface having a lowest point at a center thereof. In one embodiment, each semiconductor core structure 161 comprises a contoured bottom surface having a highest point at a center thereof. In one embodiment, the memory film 50 comprises a vertically-extending portion that vertically extends through the alternating stack (32, 42), and a laterally-protruding portion that is adjoined to a bottom end of the vertically-extending portion and laterally protruding outward from the bottom end of the vertically extending portion and laterally surrounding the annular semiconductor structure 160. In one embodiment, the semiconductor material layer 14 does not contact and is laterally spaced by the laterally-protruding portion of the memory film 50 from the annular semiconductor structure 160. The semiconductor material layer 14 can laterally surround each of the annular semiconductor structures 160. Depending on the height of the semiconductor core structure 161, an optional cavity (e.g., air gap) 69 may be located between the bottom surface of the semiconductor core structure 161 and the bottom surface of the memory film 50 at the bottom of the memory opening 49.

Referring to FIG. 8F, a semiconductor channel material layer 60L can be deposited on the memory film 50 and each of the semiconductor core structures 161 by performing a conformal deposition process. In one embodiment, the semiconductor channel material layer 60L may comprise silicon (e.g., polysilicon or amorphous silicon) which is either intrinsic or intentionally doped with dopants of the first conductivity type (e.g., p-type), which is the opposite of the second conductivity type. The atomic concentration of dopants of the first conductivity type in the semiconductor channel material layer 60L may be in a range from 1×10¹²/^{cm 3} to 3.0×10¹⁷/cm³, such as from 1×10¹⁴/cm³ to 3.0×10¹⁶/cm³, although lesser and greater atomic concentrations may also be employed. The thickness of the semiconductor channel material layer 60L may be in a range from 3 nm to 60 nm, such as from 6 nm to 30 nm, although lesser and greater thicknesses may also be employed. In one embodiment, each portion of the semiconductor channel material layer 60L located within a respective memory opening 49 may comprise a contoured bottom surface which includes two concave surfaces that contact the two respective convex surfaces of the semiconductor core structure 161. The contoured bottom surface of the semiconductor channel material layer 60L protrudes downward into a recess at the center seam between the two respective convex surfaces of the semiconductor core structure 161. A p-n junction can be formed at each interface between the semiconductor channel material layer 60L and each of the semiconductor core structures 161.

A dielectric core layer comprising a dielectric fill material, such as silicon oxide, can be deposited in remaining volumes of the memory openings 49. The dielectric core layer can be vertically recessed such that each remaining portion of the dielectric core layer has a top surface at, or about, the horizontal plane including the bottom surface of a topmost insulating layers 32. Each remaining portion of the dielectric core layer constitutes a dielectric core 62.

Referring to FIG. 8G, a doped semiconductor material having a doping of the second conductivity type (e.g., n-type) can be deposited within each recessed region above the dielectric cores 62. The dopant concentration in the deposited semiconductor material can be in a range from 5×10¹⁸/cm³ to 2×10²¹/cm³, although lesser and greater dopant concentrations can also be employed. The doped semiconductor material can be, for example, doped polysilicon. Excess portions of the deposited semiconductor material having a doping of the second conductivity type, a horizontally-extending portion of the semiconductor channel layer 60L, and a horizontally-extending potion of the memory film 50 can be removed from above the horizontal plane including the top surface of the topmost layer of the alternating stack (32, 42), for example, by chemical mechanical planarization (CMP) or a recess etch process. Each remaining portion of the doped semiconductor material having a doping of the second conductivity type constitutes a drain region 63. Each remaining portion of the semiconductor channel layer 60L (which has a doping of the first conductivity type) constitutes a vertical semiconductor channel 60.

Each contiguous combination of a memory film 50 and a vertical semiconductor channel 60 constitutes a memory stack structure 55. The set of all material portions that fills a contiguous combination of a memory opening 49 and an annular cavity 13 constitutes a memory opening fill structure 58. The set of all material portions that fills a contiguous combination of a support opening 19 and an annular cavity 13 constitutes a support pillar structure. Each memory opening fill structure 58 can be located in a memory opening 49, and can comprise a memory film 50, a vertical semiconductor channel 60, and a semiconductor cap structure (160, 161) that includes a semiconductor core structure 161 contacting a bottom end of the vertical semiconductor channel 60 and further includes an annular semiconductor structure 160 laterally surrounding the semiconductor core structure 161. In one embodiment, the annular semiconductor structure 160 has a lesser vertical extent than the semiconductor core structure 161.

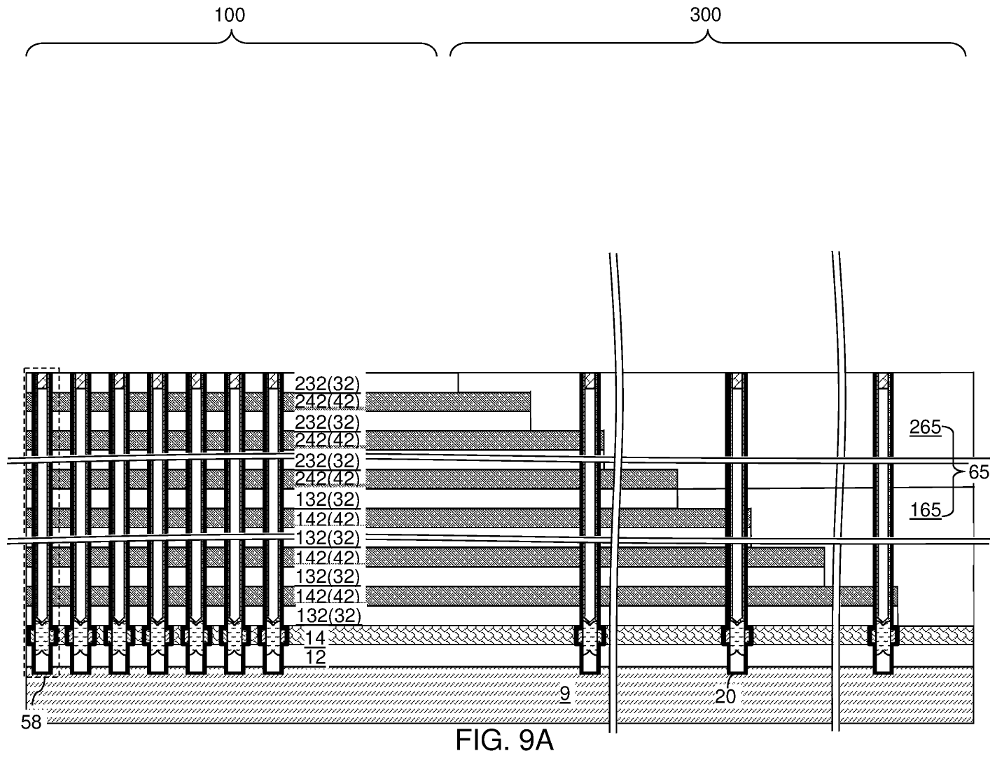

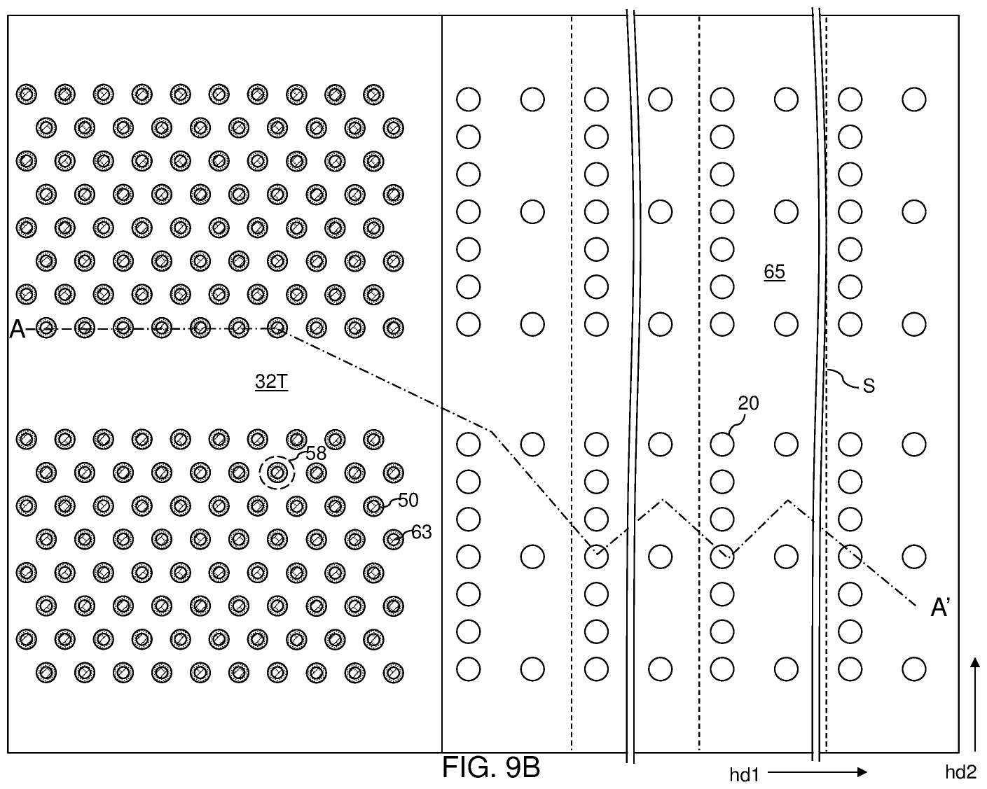

Referring to FIGS. 9A and 9B, the first exemplary structure is illustrated after formation of memory opening fill structures 58 within the memory openings 49 and formation of the support pillar structures 20 in the support openings 19. Each of the support pillar structures 20 may have a same set of materials as a memory opening fill structure 58.

In an alternative embodiment, the second-tier memory openings 249 illustrated in FIG. 6 may be filled with an additional sacrificial material, cavities can be formed in the support openings 19, and a dielectric fill material (such as silicon oxide) can be deposited in the support openings 19 to form dielectric support pillar structures in the support openings 19 while the memory openings 49 are filled with the sacrificial fill material. In this case, the dielectric support pillar structures may be formed in lieu of the support pillar structures illustrated in FIGS. 9A and 9B, and the sacrificial fill material in the memory openings 49 can be subsequently removed and the processing steps described with reference to FIGS. 8A-8G can be performed to form memory opening fill structures 58 in the respective memory openings 49. Thus, in the alternative embodiment, the support pillar structures 20 may consist essentially of at least one dielectric material (such as silicon oxide).

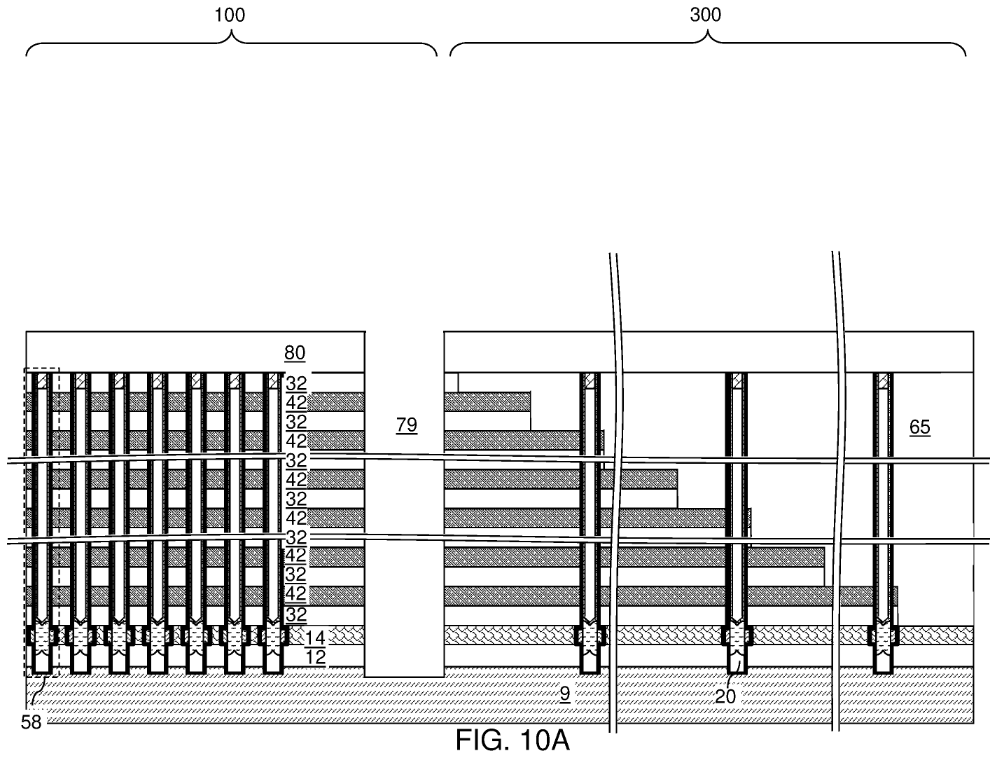

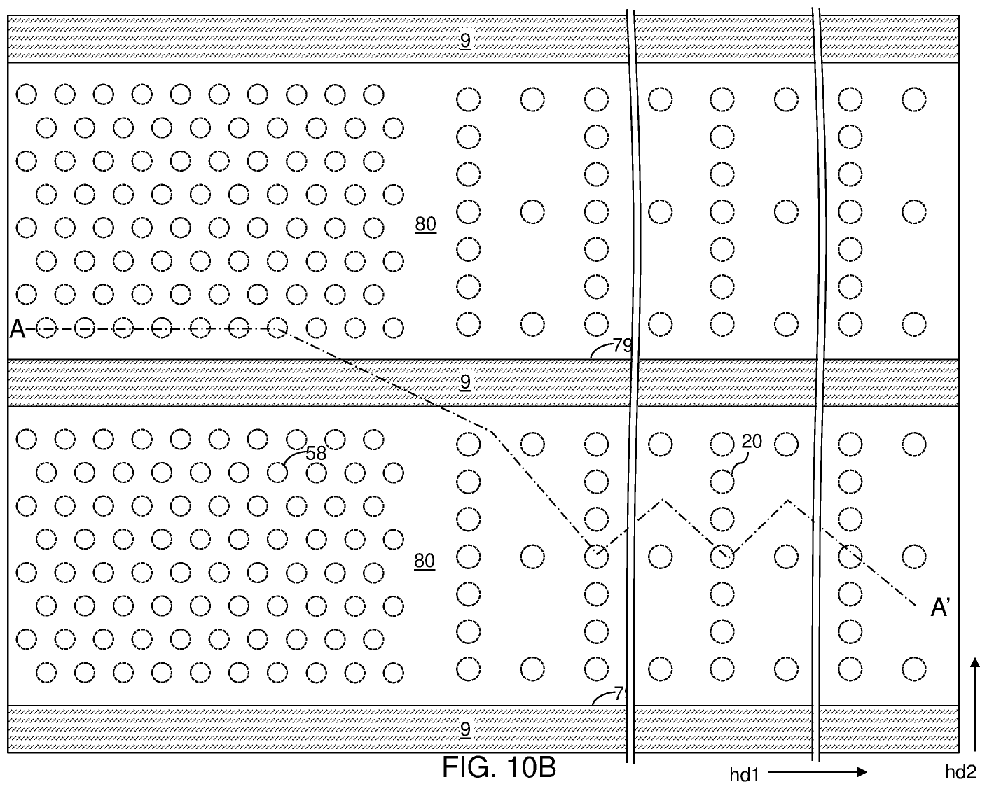

Referring to FIGS. 10A and 10B, a dielectric material, such as undoped silicate glass (i.e., silicon oxide) or a doped silicate glass can be deposited over the alternating stack (32, 42) to form a contact-level dielectric layer 80. The thickness of the contact-level dielectric layer 80 may be in a range from 100 nm to 600 nm, such as from 200 nm to 400 nm, although lesser and greater thicknesses may also be employed.

A photoresist layer (not shown) can be applied over the contact-level dielectric layer 80, and can be lithographically patterned to form elongated openings that laterally extend along the first horizontal direction hd1 between neighboring clusters of memory opening fill structures 58. An anisotropic etch process can be performed to transfer the pattern of the openings in the photoresist layer through the contact-level dielectric layer 80, the alternating stack (32, 42), and the stepped dielectric material portion 65, and at least to a top surface of the carrier substrate 9. Lateral isolation trenches 79 laterally extending along the first horizontal direction hd1 can be formed through the alternating stack (32, 42), the stepped dielectric material portion 65, and the contact-level dielectric layer 80. Each of the lateral isolation trenches 79 may comprise a respective pair of lengthwise sidewalls that are parallel to the first horizontal direction hd1 and vertically extend from the carrier substrate 9 to the top surface of the contact-level dielectric layer 80. A surface of the carrier substrate 9 can be physically exposed underneath each lateral isolation trench 79. The photoresist layer can be subsequently removed, for example, by ashing.

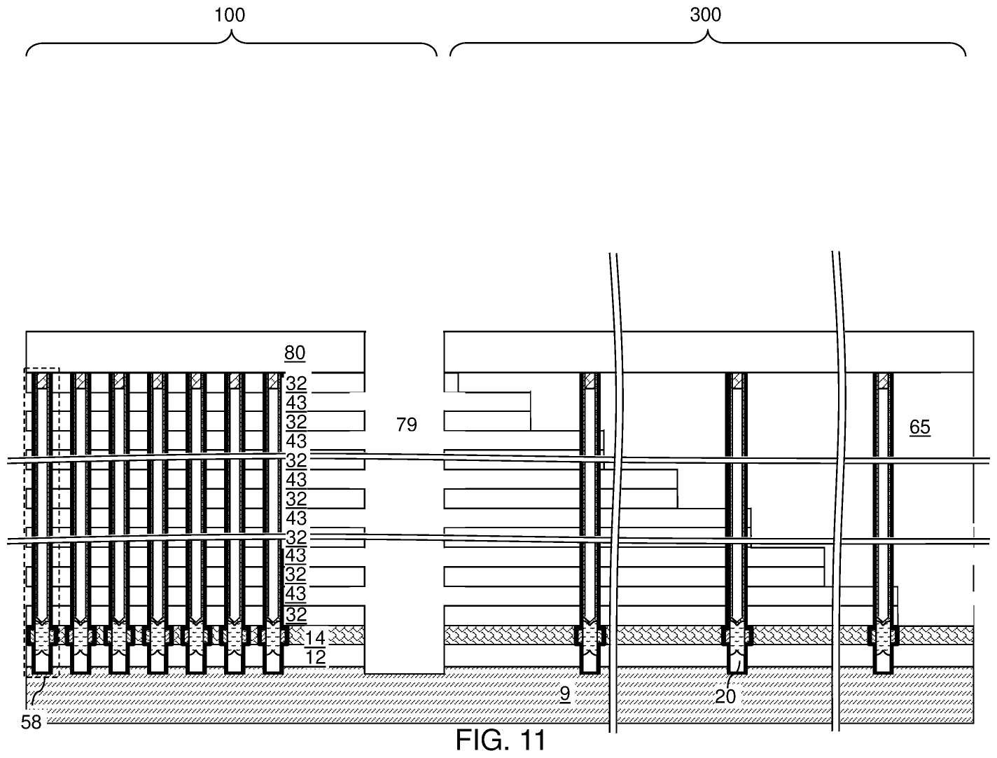

Referring to FIG. 11, an etchant that selectively etches the material of the sacrificial material layers 42 with respect to the material of the insulating layers 32, the semiconductor material layer 14, and the carrier substrate 9 can be introduced into the access trenches 79, for example, employing an isotropic etch process. Lateral recesses 43 are formed in volumes from which the sacrificial material layers 42 are removed. The removal of the sacrificial material layers 42 can be selective to the materials of the insulating layers 32, the stepped dielectric material portion 65, and the material of the outermost layer of the memory films 50. In one embodiment, the sacrificial material layers 42 can include silicon nitride, and the materials of the insulating layers 32 and the stepped dielectric material portion 65 can include silicon oxide.

The etch process that removes the second material selective to the first material and the outermost layer of the memory films 50 can be a wet etch process employing a wet etch solution, or can be a gas phase (dry) etch process in which the etchant is introduced in a vapor phase into the access trenches 79. For example, if the sacrificial material layers 42 include silicon nitride, the etch process can be a wet etch process in which the first exemplary structure is immersed within a wet etch tank including phosphoric acid, which etches silicon nitride selective to silicon oxide, silicon, and various other materials employed in the art. The support pillar structure 20, the stepped dielectric material portion 65, and the memory stack structures 55 provide structural support while the lateral recesses 43 are present within volumes previously occupied by the sacrificial material layers 42.

Each lateral recess 43 can be a laterally extending cavity having a lateral dimension that is greater than the vertical extent of the cavity. In other words, the lateral dimension of each lateral recess 43 can be greater than the height of the lateral recess 43. A plurality of lateral recesses 43 can be formed in the volumes from which the second material of the sacrificial material layers 42 is removed. The memory openings in which the memory stack structures 55 are formed are herein referred to as front side openings or front side cavities in contrast with the lateral recesses 43.

Each of the plurality of lateral recesses 43 can extend substantially parallel to the top surface of the carrier substrate 9. A lateral recess 43 can be vertically bounded by a top surface of an underlying insulating layer 32 and a bottom surface of an overlying insulating layer 32. In one embodiment, each lateral recess 43 can have a uniform height throughout.

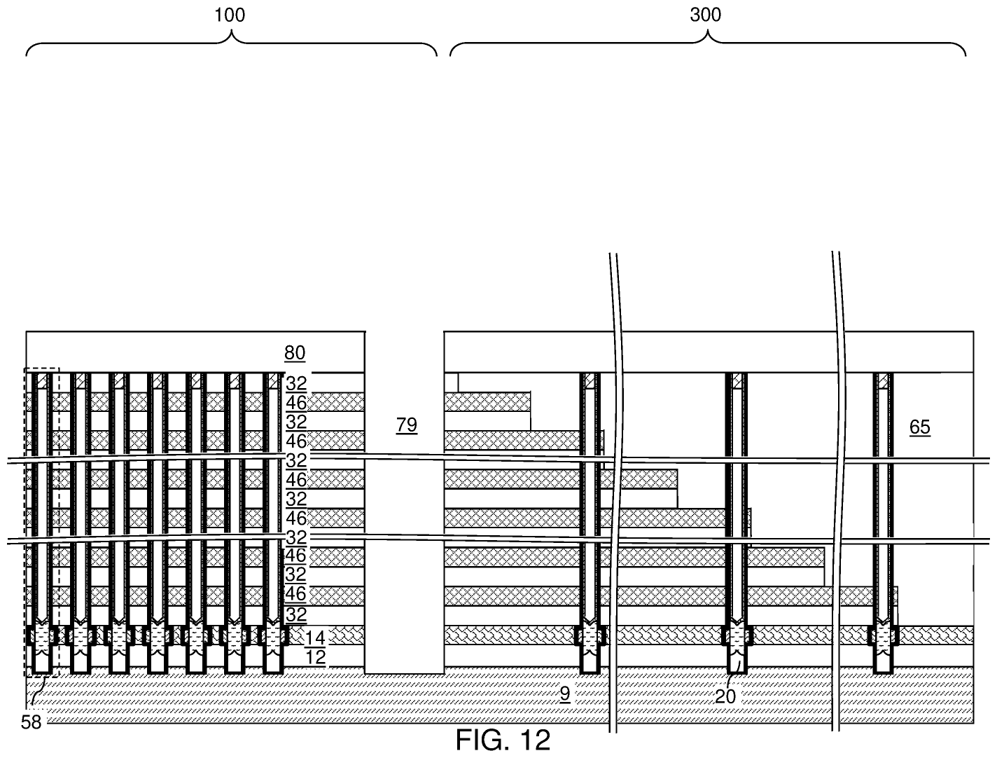

Referring to FIG. 12, an outer blocking dielectric layer (not expressly illustrated in FIG. 12) can be optionally formed. The outer blocking dielectric layer, if present, comprises a dielectric material that functions as a control gate dielectric for the control gates to be subsequently formed in the lateral recesses 43.

In case the blocking dielectric layer 52 is present within each memory opening, the outer blocking dielectric layer is optional. In case the blocking dielectric layer 52 is omitted, the outer blocking dielectric layer is present.

At least one conductive material can be deposited in the lateral recesses 43 by providing at least one reactant gas into the lateral recesses 43 through the access trenches 79. A metallic barrier layer can be deposited in the lateral recesses 43. The metallic barrier layer includes an electrically conductive metallic material that can function as a diffusion barrier layer and/or adhesion promotion layer for a metallic fill material to be subsequently deposited. The metallic barrier layer can include a conductive metallic nitride material such as TiN, TaN, WN, or a stack thereof, or can include a conductive metallic carbide material such as TiC, TaC, WC, or a stack thereof. In one embodiment, the metallic barrier layer can be deposited by a conformal deposition process such as chemical vapor deposition (CVD) or atomic layer deposition (ALD). The thickness of the metallic barrier layer can be in a range from 2 nm to 8 nm, such as from 3 nm to 6 nm, although lesser and greater thicknesses can also be employed. In one embodiment, the metallic barrier layer can consist essentially of a conductive metal nitride such as TiN.

A metal fill material is deposited in the plurality of lateral recesses 43, on the sidewalls of the at least one the access trench 79, and over the top surface of the contact-level dielectric layer 80 to form a metallic fill material layer. The metallic fill material can be deposited by a conformal deposition method, which can be, for example, chemical vapor deposition (CVD), atomic layer deposition (ALD), electroless plating, electroplating, or a combination thereof. In one embodiment, the metallic fill material layer can consist essentially of at least one elemental metal. The at least one elemental metal of the metallic fill material layer can be selected, for example, from tungsten, cobalt, ruthenium, titanium, and tantalum. In one embodiment, the metallic fill material layer can consist essentially of a single elemental metal. In one embodiment, the metallic fill material layer can be deposited employing a fluorine-containing precursor gas such as WF₆. In one embodiment, the metallic fill material layer can be a tungsten layer including a residual level of fluorine atoms as impurities. The metallic fill material layer is spaced from the insulating layers 32 and the memory stack structures 55 by the metallic barrier layer, which is a metallic barrier layer that blocks diffusion of fluorine atoms therethrough.

A plurality of electrically conductive layers 46 can be formed in the plurality of lateral recesses 43, and a continuous metallic material layer can be formed on the sidewalls of cach access trench 79 and over the contact-level dielectric layer 80. Each electrically conductive layer 46 includes a portion of the metallic barrier layer and a portion of the metallic fill material layer that are located between a vertically neighboring pair of dielectric material layers such as a pair of insulating layers 32. The continuous metallic material layer includes a continuous portion of the metallic barrier layer and a continuous portion of the metallic fill material layer that are located in the access trenches 79 or above the contact-level dielectric layer 80.

The deposited metallic material of the continuous electrically conductive material layer is etched back from the sidewalls of each access trench 79 and from above the contact-level dielectric layer 80 by performing an isotropic etch process that etches the at least one conductive material of the continuous electrically conductive material layer. Each remaining portion of the deposited metallic material in the lateral recesses 43 constitutes an electrically conductive layer 46. Each electrically conductive layer 46 can be a conductive line structure. Thus, the sacrificial material layers 42 are replaced with the electrically conductive layers 46. Generally, the electrically conductive layers 46 can be formed by providing a metallic precursor gas into the lateral isolation trenches 79 and into the lateral recesses 43.

At least one uppermost electrically conductive layer 46 may comprise a drain side select gate electrode. At least one bottommost electrically conductive layer 46 may comprise a source side select gate electrode. The remaining electrically conductive layers 46 may comprise word lines. Each word line functions as a common control gate electrode for the plurality of vertical NAND strings (e.g., memory opening fill structures 58).

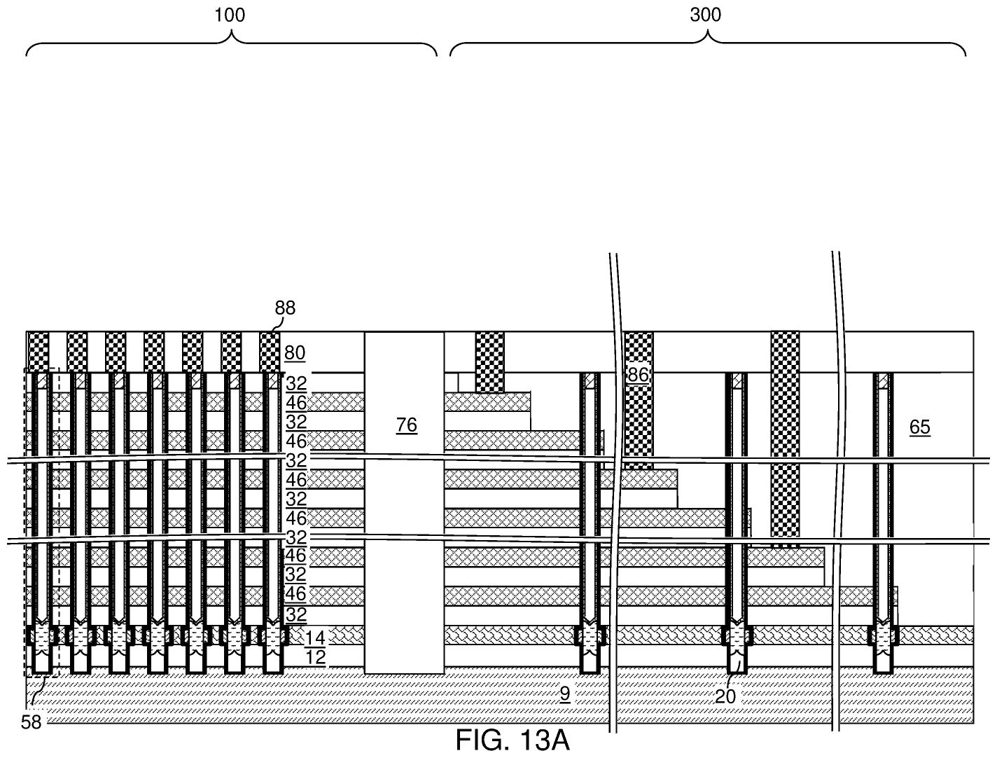

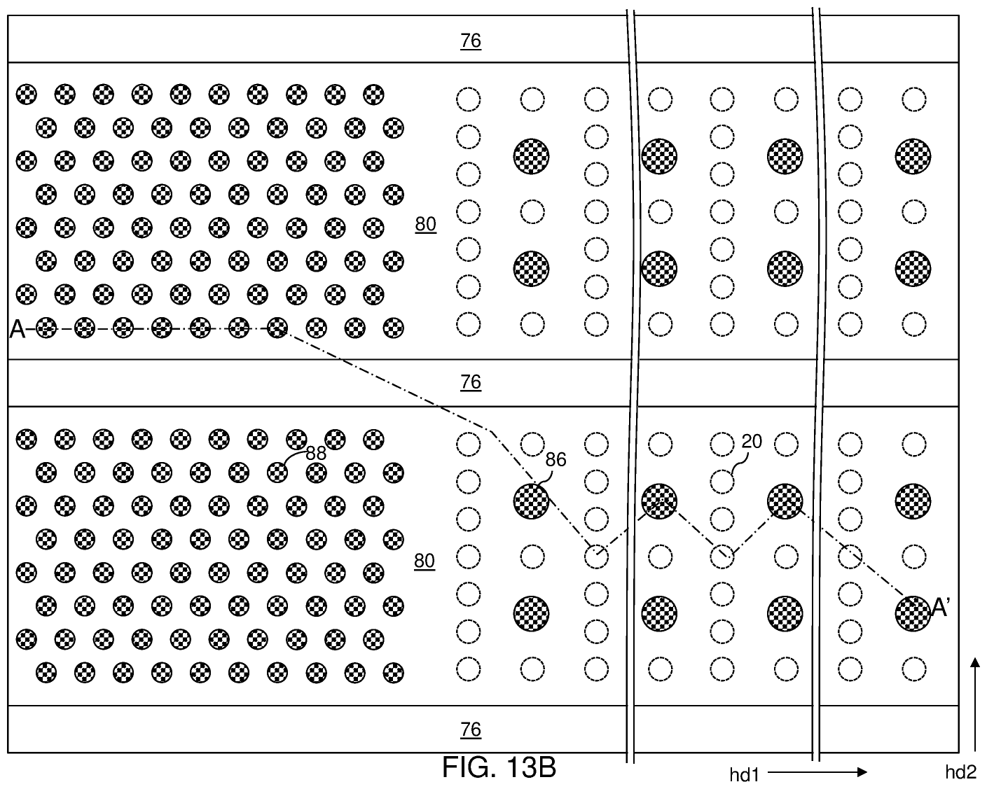

Referring to FIGS. 13A and 13B, a dielectric fill material, such as silicon oxide can be deposited in the lateral isolation trenches 79. Excess portions of the dielectric fill material can be removed from above the contact-level dielectric layer 80. Each remaining portion of the dielectric fill material that fills a respective one of the lateral isolation trenches 79 constitutes a lateral isolation trench fill structure 76, which may be a dielectric wall structure. In an alternative embodiment, an insulating spacer having a tubular configuration can be formed in peripheral portions of each of the lateral isolation trenches 79, and a through-stack conductive via structure may be formed within a respective one of the insulating spacers. In this case, each lateral isolation trench fill structure 76 may comprise a combination of a through-stack conductive via structure and an insulating spacer that laterally surrounds the through-stack conductive via structure.

Contact via structures (88, 86) can be formed through the contact-level dielectric layer 80, and optionally through the stepped dielectric material portion 65. For example, drain contact via structures 88 can be formed through the contact-level dielectric layer 80 on each drain region 63. Layer contact via structures 86 can be formed on the electrically conductive layers 46 through the contact-level dielectric layer 80, and through the stepped dielectric material portion 65.

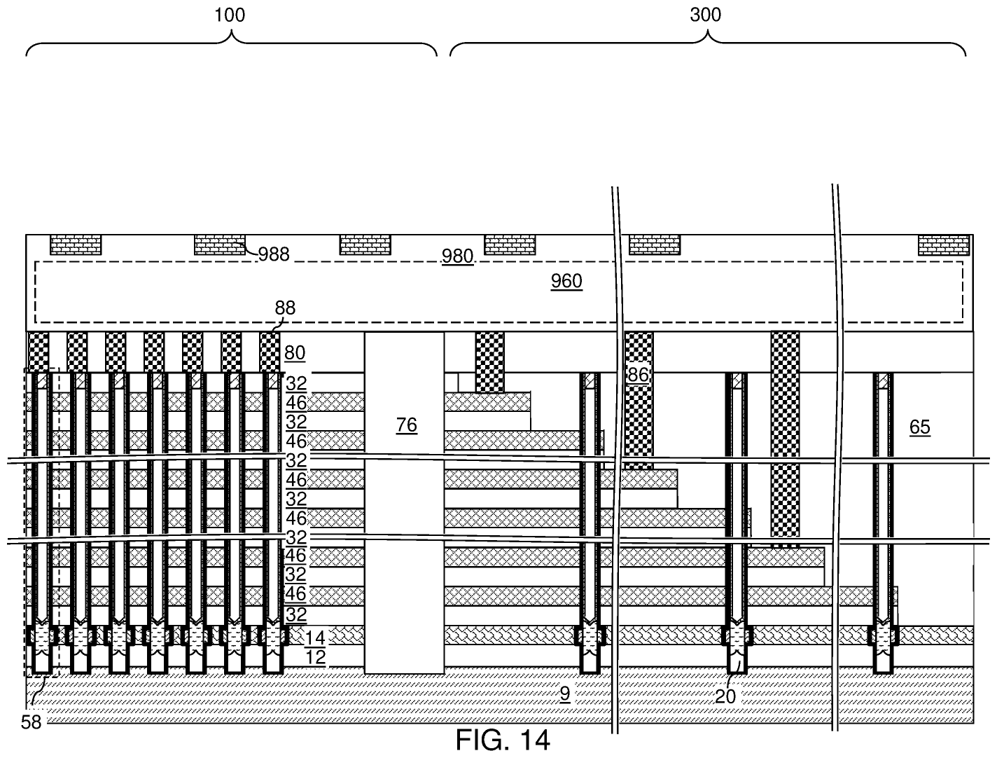

Referring to FIG. 14, additional dielectric material layers and additional metal interconnect structures can be formed over the contact-level dielectric layer 80. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The additional dielectric material layers that are formed above the contact-level dielectric layer 80 are herein referred to as memory-side dielectric material layers 960. The additional metal interconnect structures are collectively referred to as memory-side dielectric material layers 960. The memory-side dielectric material layers 960 comprise a bit-line-level dielectric material layer embedding bit lines, which are a subset of the memory-side metal interconnect structures 980.

Metal bonding pads, which are herein referred to as upper bonding pads 988, may be formed at the topmost level of the memory-side dielectric material layers 960. The upper bonding pads 988 may be electrically connected to the memory-side metal interconnect structures 980 and various nodes of the three-dimensional memory array including the electrically conductive layers 46 and the memory opening fill structures 58. A memory die 900 can thus be provided.

The memory-side dielectric material layers 960 are formed over the alternating stacks (32, 46). The memory-side metal interconnect structures 980 are embedded in the memory-side dielectric material layers 960. The memory-side bonding pads 988 can be embedded within the memory-side dielectric material layers 960, and specifically, within the topmost layer among the memory-side dielectric material layers 960. The memory-side bonding pads 988 can be electrically connected to the memory-side metal interconnect structures 980.

In one embodiment, the memory die 900 may comprise: a three-dimensional memory array underlying the first dielectric material layer 110 and comprising an alternating stack (32, 46) of insulating layers 32 and electrically conductive layers 46, a two-dimensional array of memory openings 49 vertically extending through the alternating stack (32, 46), and a two-dimensional array of memory opening fill structures 58 located in the two-dimensional array of memory openings 49 and comprising a respective vertical stack of memory elements and a respective vertical semiconductor channel 60; and a two-dimensional array of contact via structures (such as the drain contact via structures 88) overlying the three-dimensional memory array and electrically connected to a respective one of the vertical semiconductor channels 60.

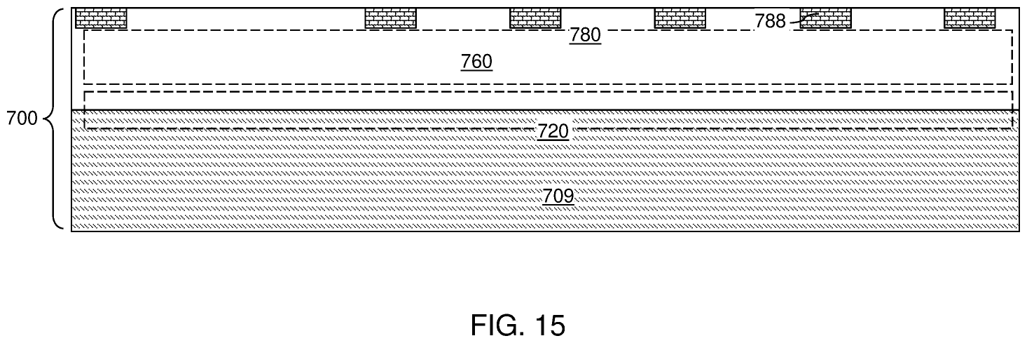

Referring to FIG. 15, a logic die 700 can be provided. The logic die 700 includes a logic-side substrate 709, a peripheral circuit 720 located on the logic-side substrate 709 and comprising logic-side semiconductor devices (such as field effect transistors), logic-side metal interconnect structures 780 embedded within logic-side dielectric material layers 760, and logic-side bonding pads 778. The peripheral circuit 720 can be configured to control operation of the memory array within the memory die 900. Specifically, the peripheral circuit 720 can be configured to drive various electrical components within the memory array including, but not limited to, the electrically conductive layers 46, the drain regions 63, and a source contact structure to be subsequently formed. The peripheral circuit 720 can be configured to control operation of the vertical stack of memory elements in the memory array in the memory die 900.

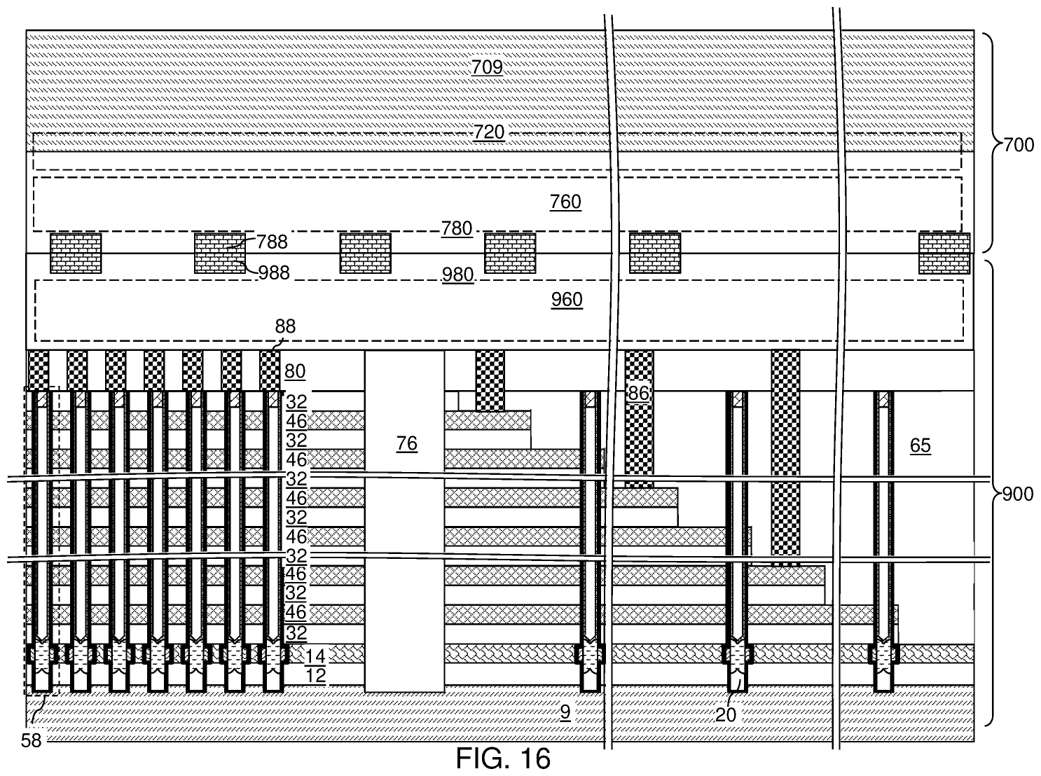

Referring to FIG. 16, the logic die 700 can be attached to the memory die 900, for example, by bonding the logic-side bonding pads 788 to the memory-side bonding pads 988 at a bonding interface. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

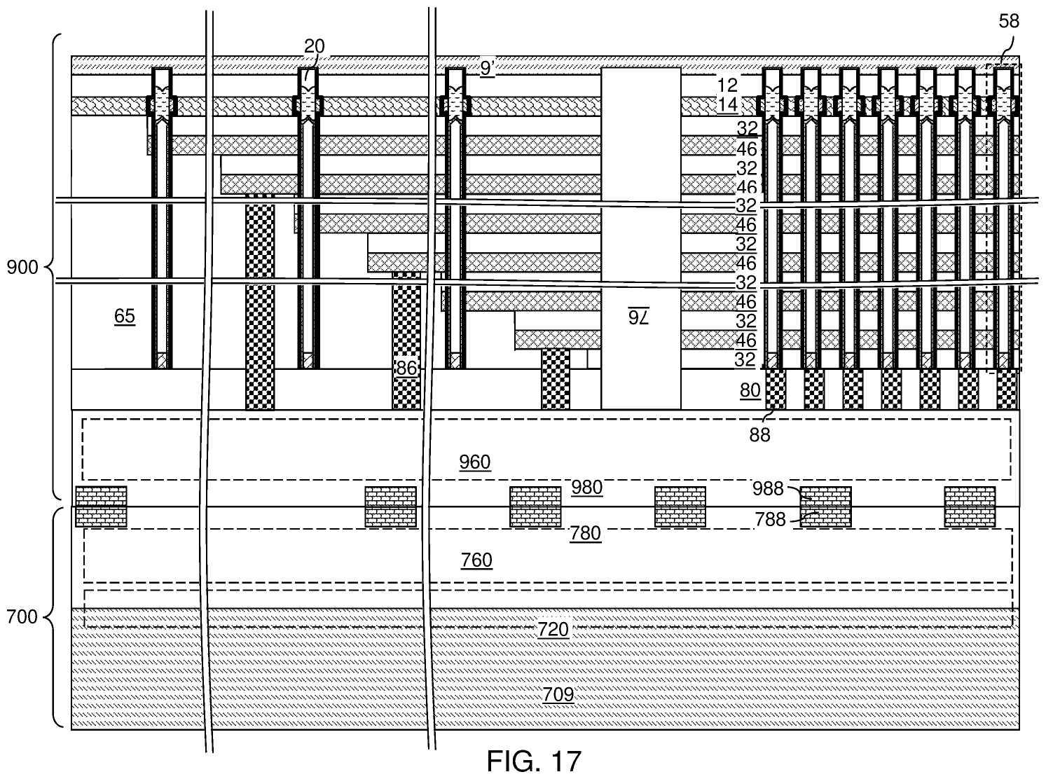

Referring to FIG. 17, at least a backside portion of the carrier substrate 9 can be removed, for example, by grinding, polishing, cleaving, an isotropic etch process, and/or an anisotropic etch process. In one embodiment, a thinned carrier substrate 9′ may be remain after removing the backside of the carrier substrate 9. The thinned carrier substrate 9′ may have a thickness in a range from 0.1 micron to 10 microns, although lesser and greater thicknesses may also be employed. Alternatively, the entire carrier substrate 9 may be removed during the step shown in FIG. 17.

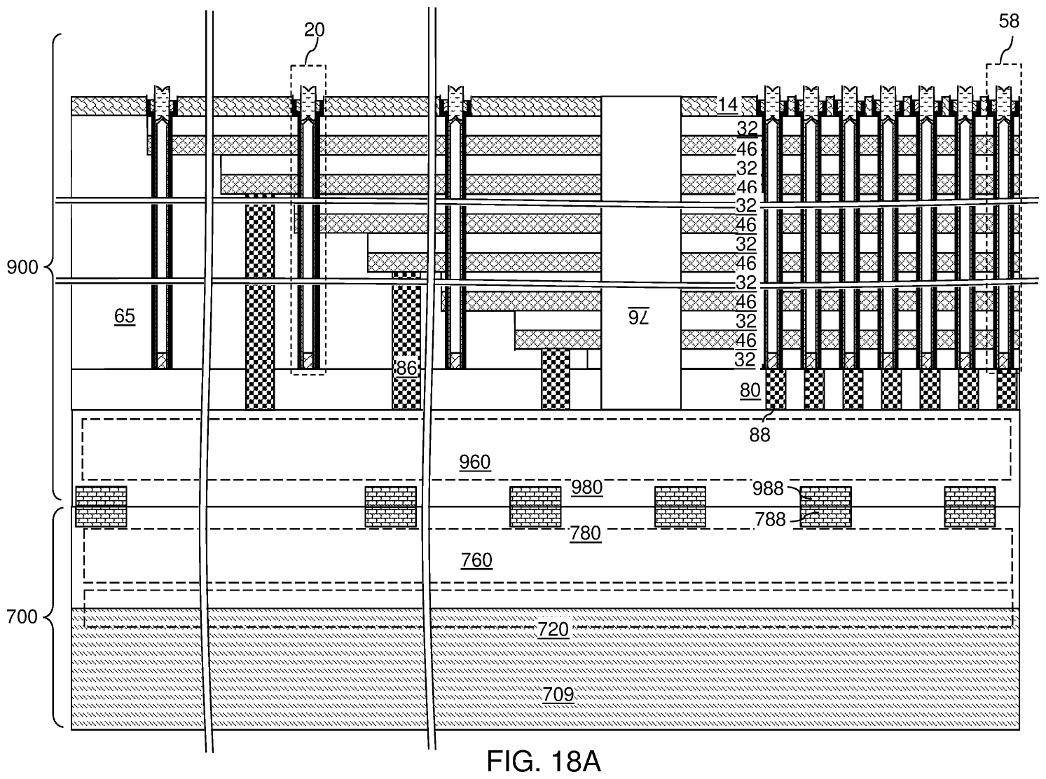

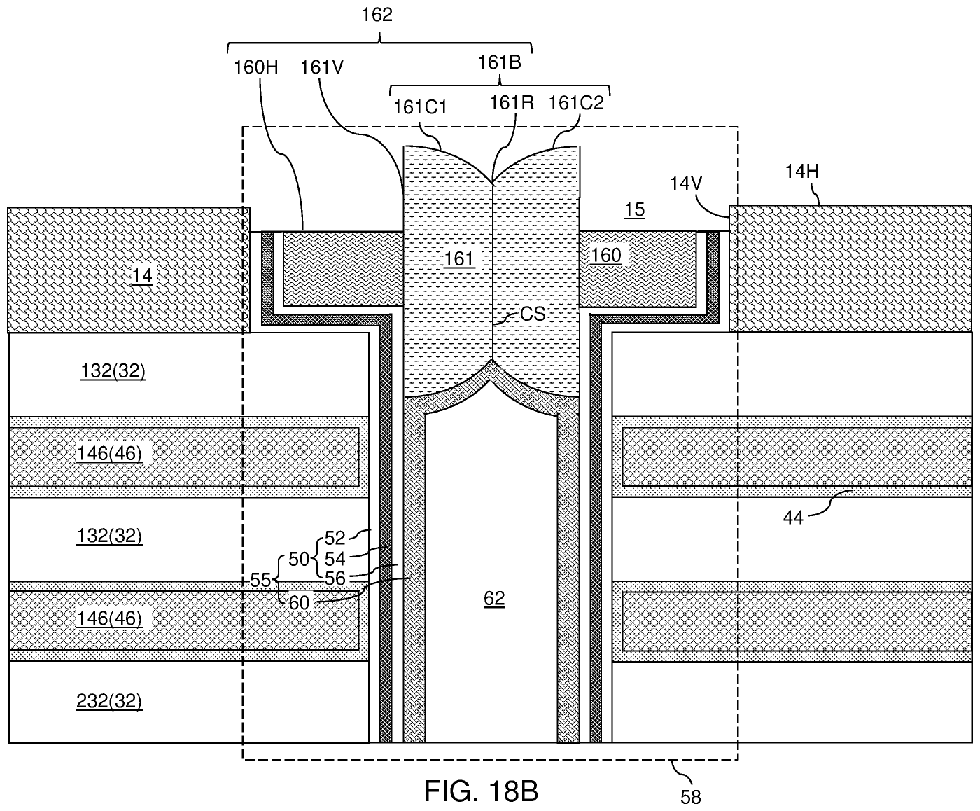

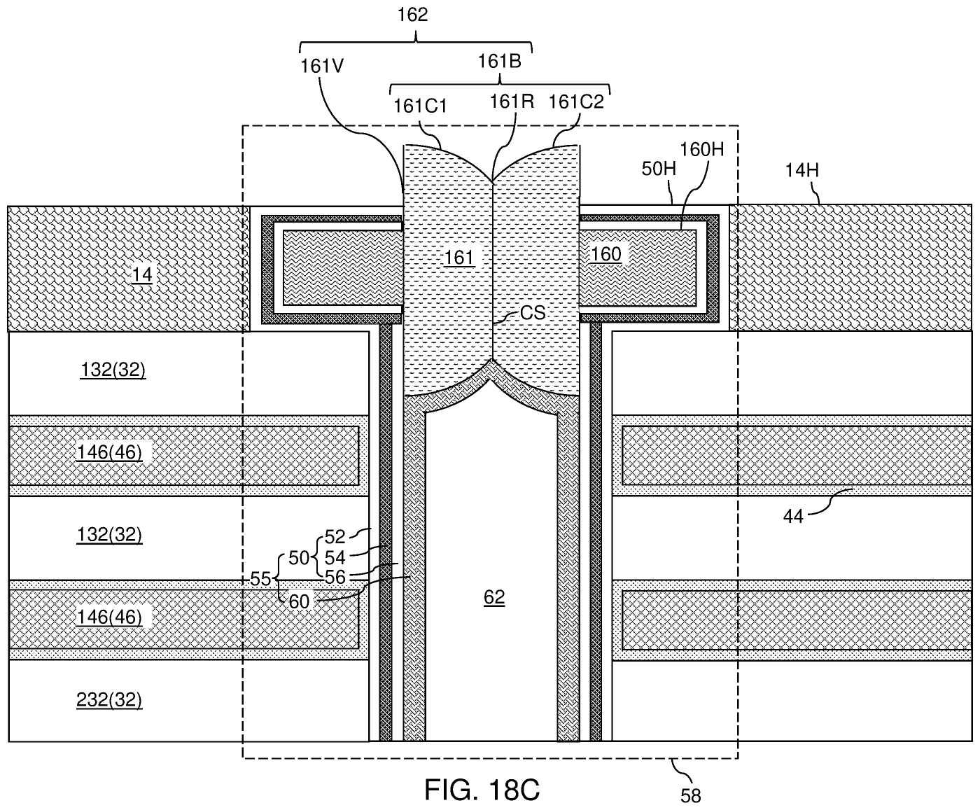

Referring to FIGS. 18A and 18B, if the thinned carrier substrate 9′ is still present, then it may be removed, for example, by performing an etch process that removes the material of the thinned carrier substrate 9′ selective to the material of the buried insulating layer 12. For example, if the thinned carrier substrate 9′ comprises silicon, then a wet etch process employing KOH may be performed to remove the thinned carrier substrate 9′ selective to the buried insulating layer 12.

Subsequently, the buried insulating layer 12 and a bottom portion of each memory film 50 may be removed selective to the semiconductor materials of the semiconductor material layer 14 and the semiconductor cap structures (160, 161). In an illustrative example, the buried insulating layer 12 and bottom portions of the memory films 50 can be removed by performing an isotropic etch process, such as a wet etch process employing dilute hydrofluoric acid or a chemical dry etch process. The bottom surface of the semiconductor material layer 14 and the bottom surfaces of the semiconductor cap structures (160, 161) can act as an etch stop and be exposed after the isotropic etch process.

As shown in FIG. 18B, the backside surface 162 of each semiconductor cap structure (160, 161) may comprise a planar annular horizontal backside surface 160H of the annular semiconductor structure 160, a cylindrical vertical surface segment 161V of the semiconductor core segment 161, and a contoured bottom surface 161B of the semiconductor core segment 161 having two opposing convex surfaces 161C1 and 161C2 which meet at a recess 161R above the central seam CS of the semiconductor core segment 161. In one embodiment, a cylindrical vertical surface segment 14V of the semiconductor material layer 14 may be physically exposed around each opening 15 through the semiconductor material layer 14 around a respective memory opening fill structure 58. The cylindrical vertical surface segment 14V adjoins an edge of the horizontal backside surface 14H of the semiconductor material layer 14. Outer blocking dielectric layers 44 embedding the electrically conductive layers 46 are expressly shown.

In an alternative configuration of the first exemplary structure shown in FIG. 18C, the horizontal portion 50H of the memory film 50 overlying the horizontal bottom surface 160H of the annular semiconductor structure 160 is not removed. In this alternative configuration, the annular semiconductor structure 160 is not exposed after removing buried insulating layer 12.

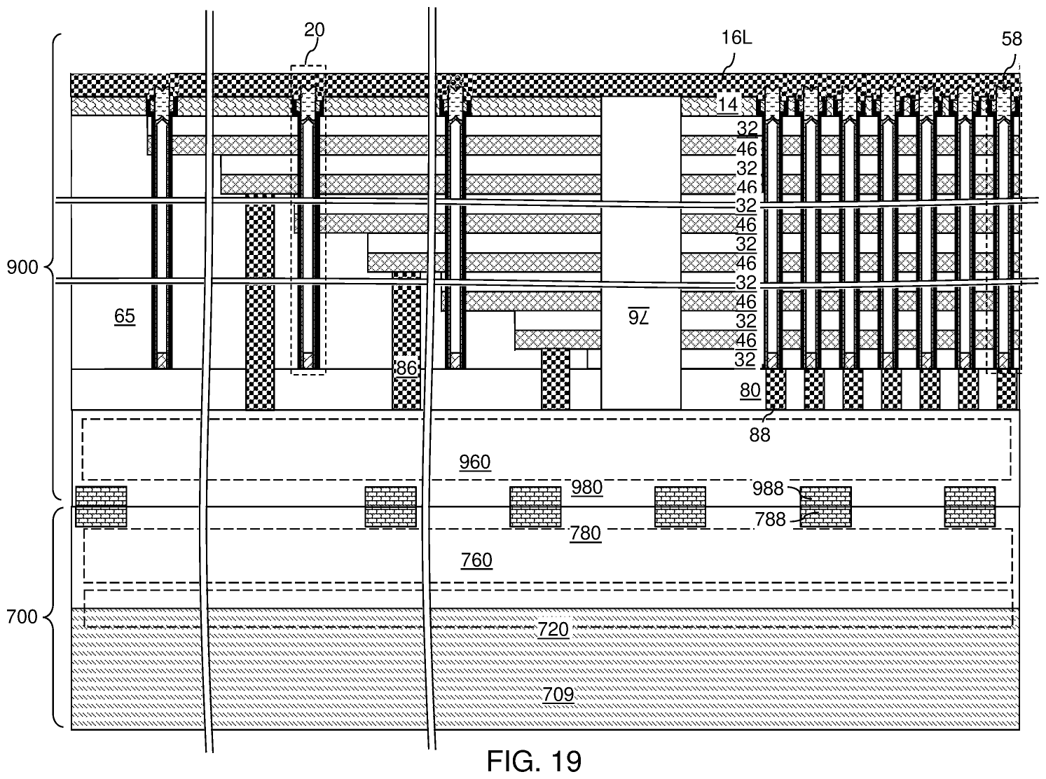

Referring to FIG. 19, at least one electrically conductive material may be deposited on the physically exposed backside surface of the semiconductor material layer 14 and on the physically exposed backside surfaces 162 of the semiconductor cap structures (160, 161) to form a source layer 16. In one embodiment, the source layer 16 may comprise at least one electrically conductive material. In one embodiment, the at least one metallic material may comprise a metallic barrier material (such as TiN, TaN, WN, MON, TiC. TaC, or WC) and a high conductivity metal material (such as Cu, Mo, Co, Ru, W, etc.).

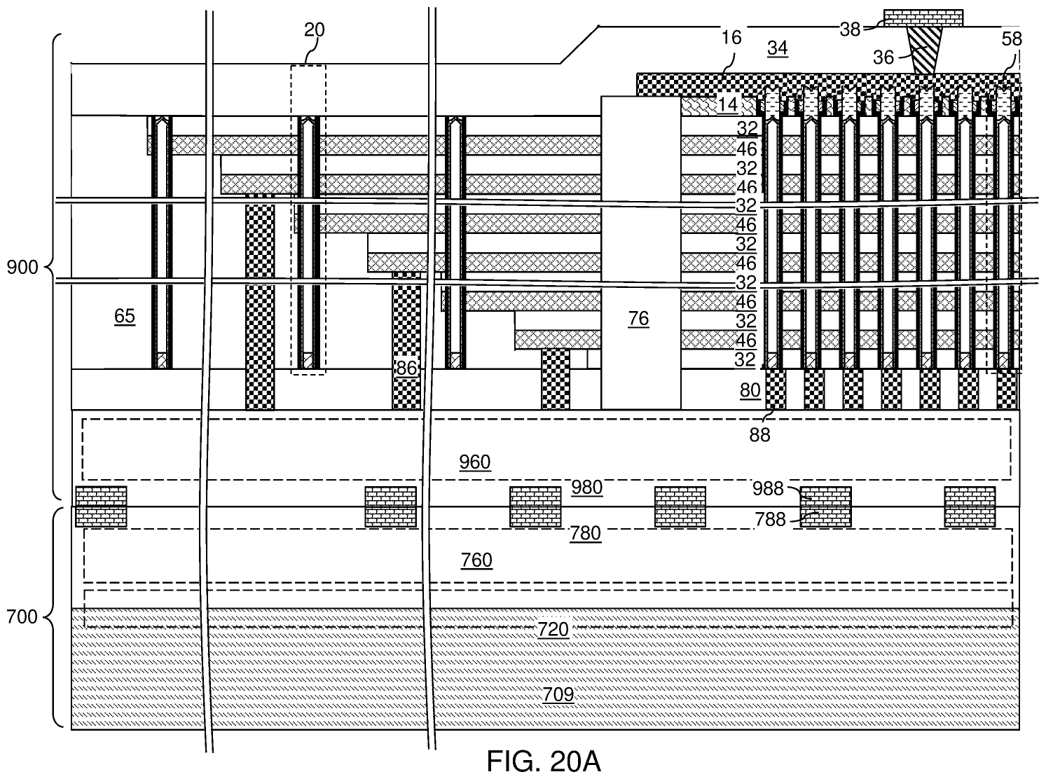

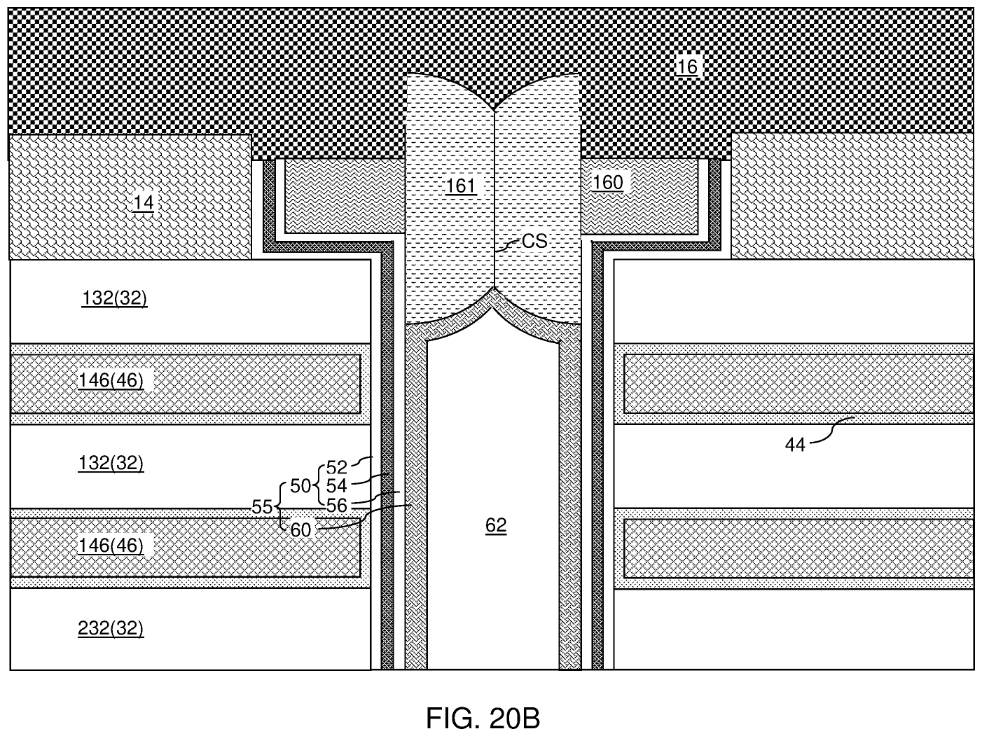

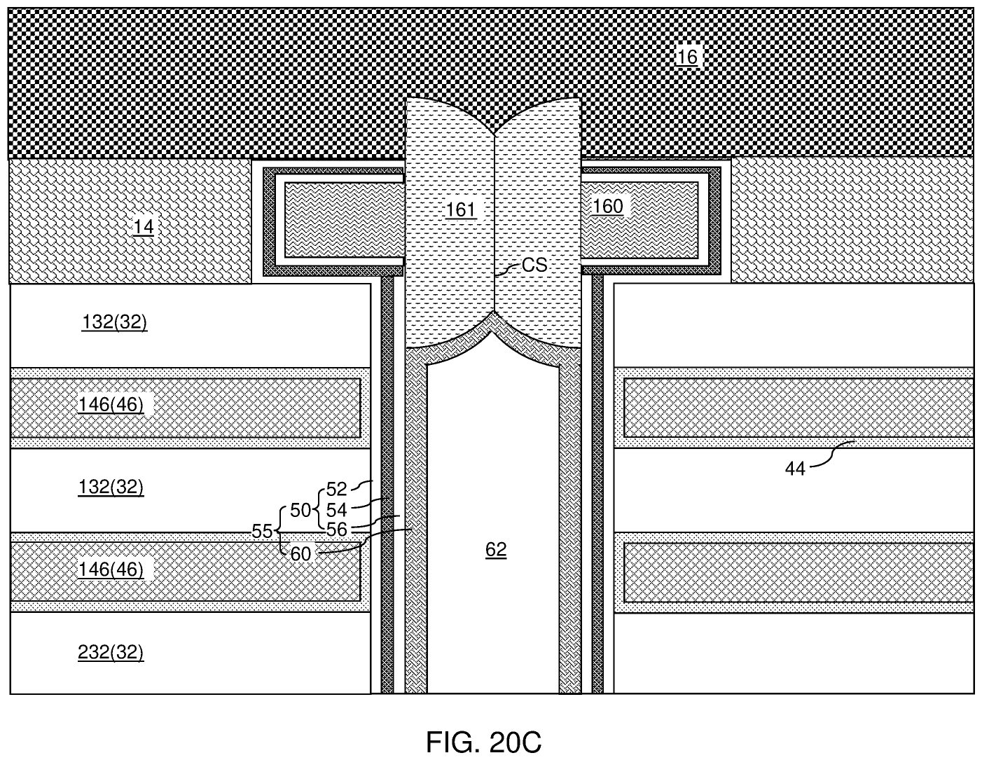

Referring to FIGS. 20A and 20B, the source layer 16 may be patterned, for example, employing a combination of lithographic methods and at least one etch process. A backside insulating layer 34 may be formed over the patterned source layer 16. At least one source contact structure (36, 38) can optionally be formed through the backside insulating layer 34 on the backside surface of the source layer 16. Each source contact structure (36, 38) may comprise a metal via structure 36 and a metal pad structure 38. The metal pad structures 38 may be employed as bonding pads for C4 bonding or wirebonding. Alternatively or additionally, the patterned source layer 16 may be controlled by a respective source control circuit in the logic die 700 using an interconnect (not shown) which extends through the memory die 900.

In the configuration of FIG. 20B which is derived from the configuration of FIG. 18B, the source layer 16 is formed on the exposed surfaces 161V and 161B of the semiconductor core structure 161 and the horizontal backside surface 160H of the annular semiconductor structure 160. In this configuration, the source layer 16 contacts the bottom surface 162 of the semiconductor core structure 161 and the annular semiconductor structure 160. In one embodiment, the source layer 16 contacts a horizontal backside surface 14H of the semiconductor material layer 14 and a vertical surface segment 14V of a sidewall of an opening 15 in the semiconductor material layer 14.

In the alternative configuration of FIG. 20C which is derived from the alternative configuration of FIG. 18C, the source layer 16 is formed on the exposed surfaces 161V and 161B of the semiconductor core structure 161 but not on the horizontal backside surface 160H the annular semiconductor structure 160. Instead, the source layer 16 is formed on the horizontal portion 50H of the memory film 50 which covers the horizontal backside surface 160H of the annular semiconductor structure 160. Thus, in this alternative configuration, the source layer 16 contacts the semiconductor core structure 161 but does not contact the annular semiconductor structure 160. In one embodiment, the source layer 16 contacts a horizontal backside surface 14H of the semiconductor material layer 14 but does not contact a vertical surface segment of the semiconductor material layer 14.

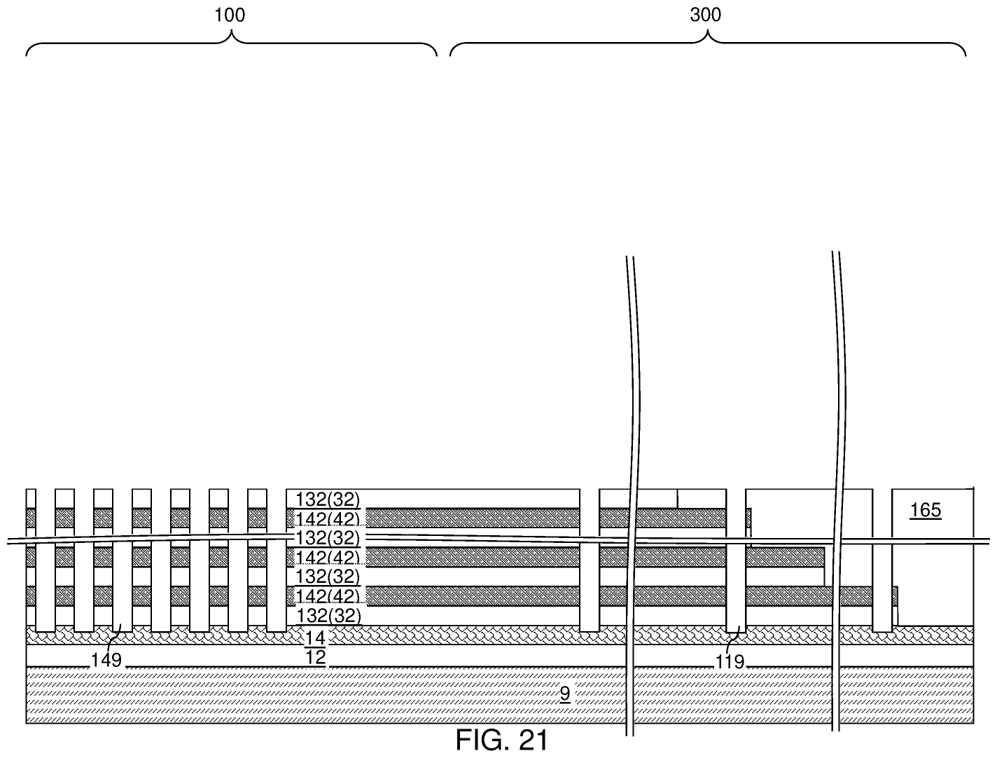

Referring to FIG. 21, a second exemplary structure according to a second embodiment of the present disclosure can be derived from the first exemplary structure of FIG. 3 by increasing the thickness of the semiconductor material layer 14 and by reducing the depth of the first-tier memory openings 149 and the first-tier support openings 119. The thickness of the semiconductor material layer 14 may be at least 100 nm, such as in a range of 100 nm to 500 nm. The chemistry of the anisotropic etch process that etches the materials of the first-tier alternating stack (132, 142) may be selected such that the bottom surfaces of the first-tier memory openings 149 and the first-tier support openings 119 are formed at or below the horizontal plane including the top surface of the semiconductor material layer 14. In other words, in the second embodiment, the first-tier memory openings 149 and the first-tier support openings 119 extend to or into the semiconductor material layer 14, but not all the way through the semiconductor material layer 14.

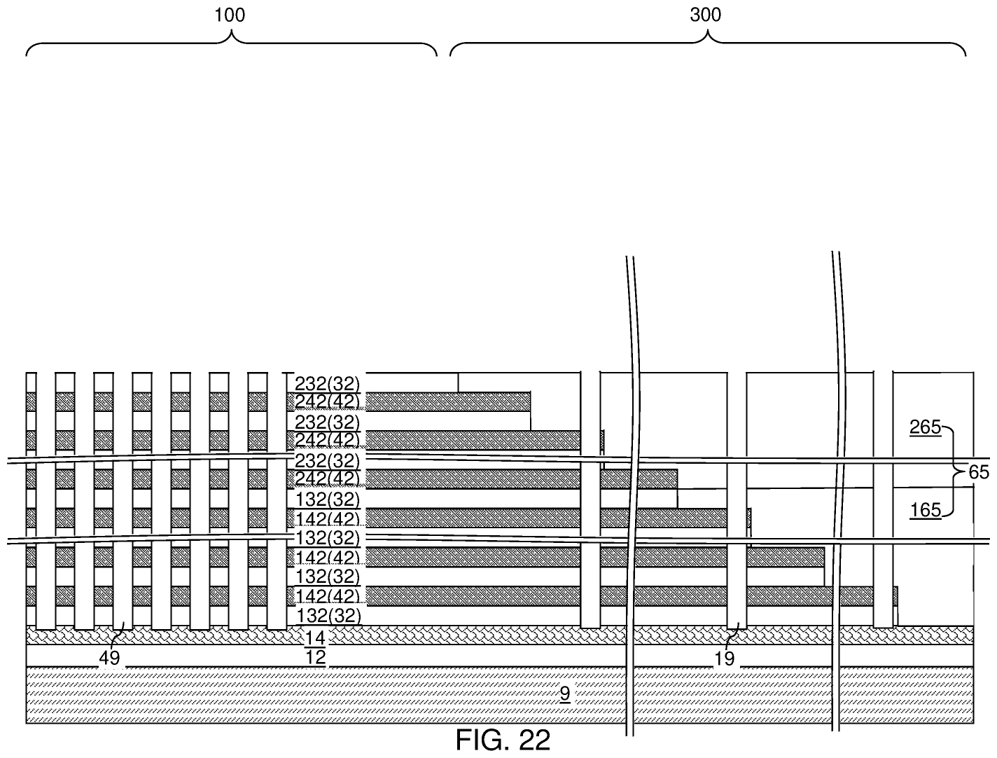

Referring to FIG. 22, the processing steps described with reference to FIGS. 4-7B may be performed to form sacrificial opening fill structures (148, 118), to form a second-tier alternating stack of second insulating layers 232 and second sacrificial material layers 242 and stepped surfaces thereupon, a second stepped dielectric material portion 265, and second-tier openings (249, 219), and to form memory openings 49 and support openings 19 by removing the sacrificial opening fill structures (148, 118).

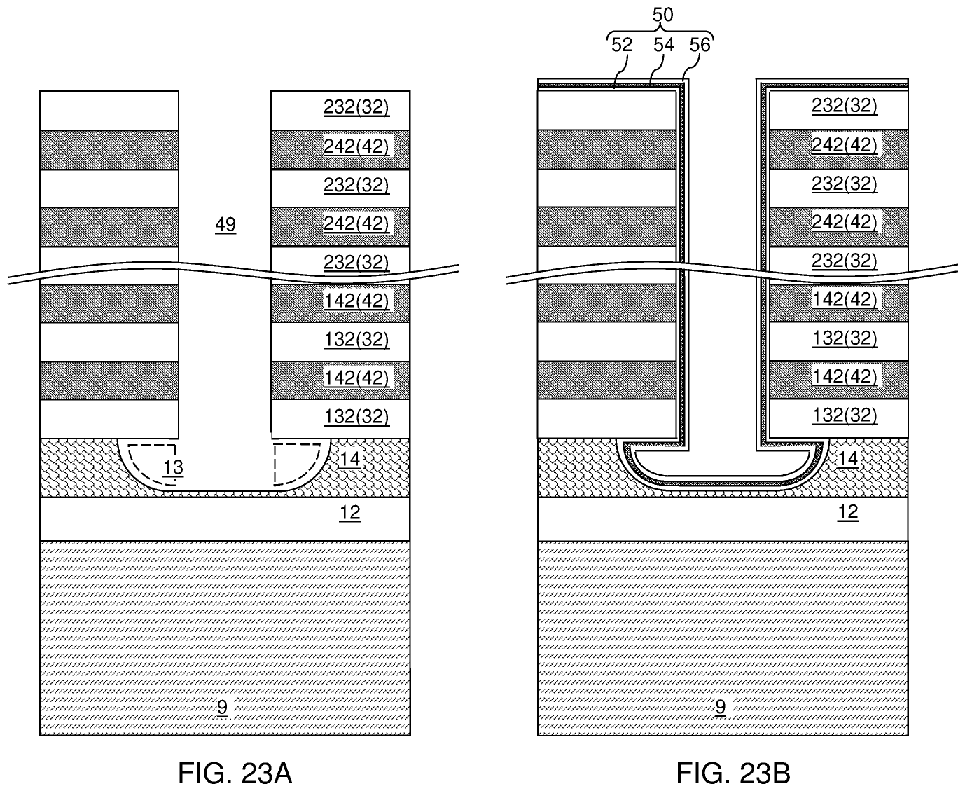

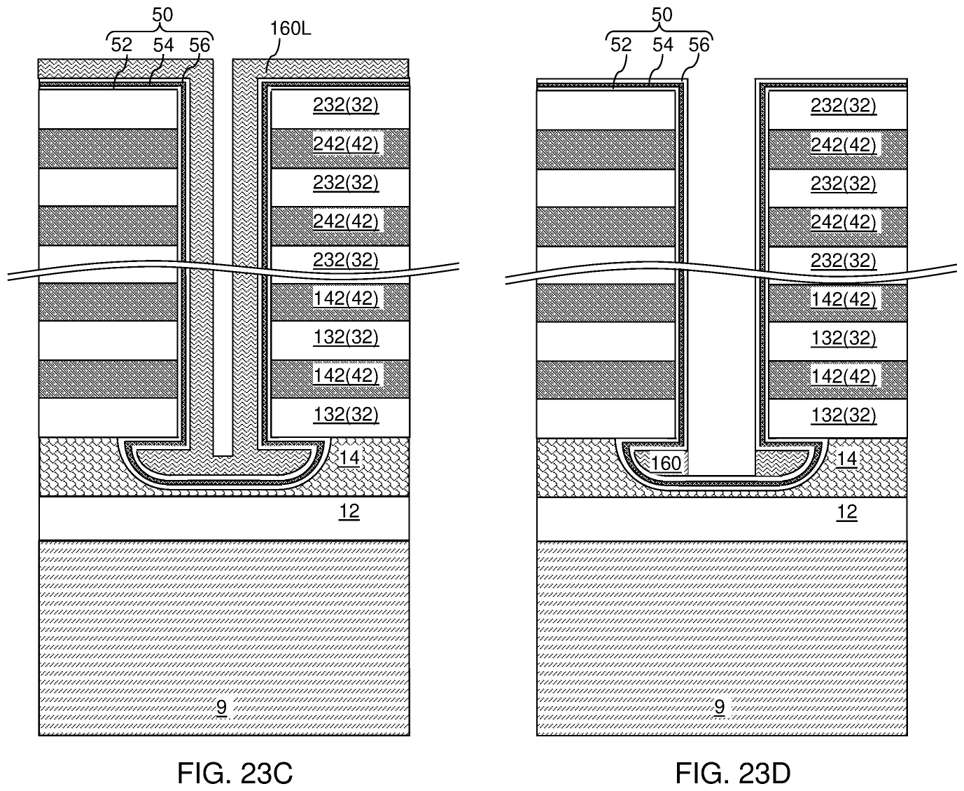

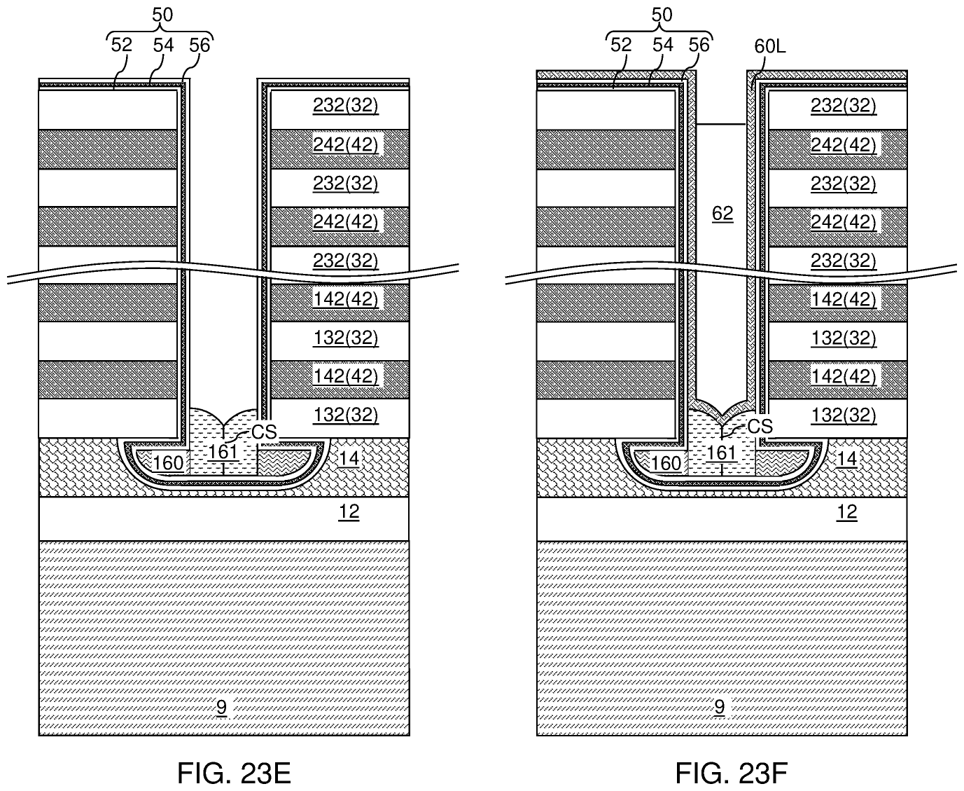

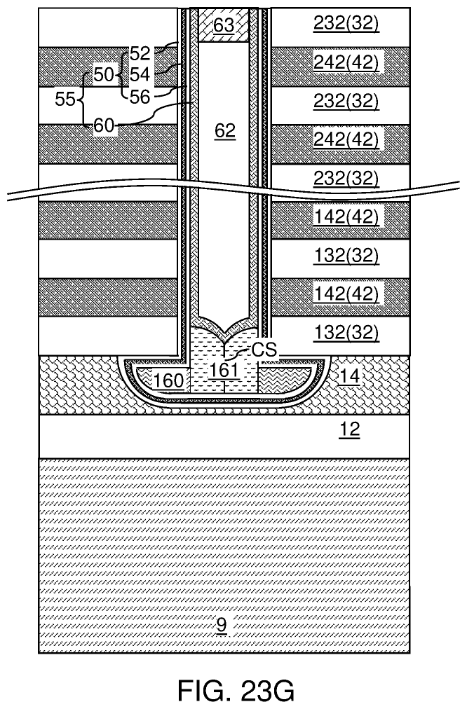

FIGS. 23A-23G are sequential vertical cross-sectional views of a memory opening 49 during formation of a memory opening fill structure 58 in the second exemplary structure according to the second embodiment of the present disclosure.

Referring to FIG. 23A, an isotropic etch process that etches the semiconductor material of the semiconductor material layer 14 selective to the materials of the alternating stack (32, 42) can be performed. For example, a wet etch process employing trimethyl-2 hydroxyethyl ammonium hydroxide (TMY), tetramethylammonium hydroxide (TMAH) or dilute potassium hydroxide may be performed to isotropically etch the semiconductor material of the semiconductor material layer 14 from underneath the memory openings 49 and the support openings 19.

The duration of the isotropic etch process may be selected such that the semiconductor material layer 14 is not etched all the way through after the isotropic etch process. Since the wet etch process does not reach the carrier substrate 9, the carrier substrate 9 may comprise any material, such as a doped or undoped silicon, or another material. An annular cavity 13 is formed within each volume from which the semiconductor material of the semiconductor material layer 14 is removed. Generally, a bottom surface of each memory opening 49 may be formed at a top surface of the semiconductor material layer 14 or within the semiconductor material layer 14. Each annular cavity 13 can be formed by isotropically recessing a portion of the semiconductor material layer 14 that is proximal to a respective memory opening 49.

Referring to FIG. 23B, the processing steps described with reference to FIG. 8B can be performed to form a memory film 50. The memory film 50 can be conformally formed, and thus, may have a uniform thickness throughout.

Referring to FIG. 23C, the processing steps described with reference to FIG. 8C can be performed to form a semiconductor fill material layer 160L.

Referring to FIG. 23D, the processing steps described with reference to FIG. 8D can be performed to form an annular semiconductor structure 160 within each annular cavity 13. In one embodiment, each annular semiconductor structure 160 may have a respective cylindrical sidewall that is vertically coincident with an inner cylindrical sidewall of a respective overlying portion of the memory film 50.

Referring to FIG. 23E, the processing steps described with reference to FIG. 8E can be performed to form a semiconductor core structure 161 on a cylindrical sidewall of each annular semiconductor structure 160. In the second exemplary structure, the memory openings 49 do not extend below the bottom surface of the semiconductor material layer 14. As such, the bottom surface of each semiconductor core structure 161 may contact a horizontal top surface of a respective horizontally-extending portion of the memory film 50 that underlies the cavity within a respective memory opening 49.

In one embodiment, the semiconductor core structure 161 comprises a center seam CS that vertically extends from a center of a top surface thereof to a center of a bottom surface thereof. In one embodiment, the semiconductor core structure 161 comprises a contoured top surface having a periphery that is raised above a center point of the contoured top surface. In one embodiment, the contoured top surface of the semiconductor core structure 161 comprises two opposing convex surfaces.

In one embodiment, each semiconductor core structure 161 comprises a horizontal bottom surface located within a same horizontal plane as a horizontally-extending portion of a bottom surface of a respective annular semiconductor structure 160. In one embodiment, the bottom surface of each annular semiconductor structure 160 may comprise a tapered convex annular surface having a bottom periphery that is adjoined to an outer periphery of the horizontally-extending portion of the bottom surface of the respective annular semiconductor structure 160.

The semiconductor material layer 14 may laterally surround and may embed each annular semiconductor structure 160. In one embodiment, the memory film 50 comprises a vertically-extending portion that vertically extends through the alternating stack (32, 42), and a laterally-protruding portion that is adjoined to a bottom end of the vertically-extending portion and laterally protruding outward from the bottom end of the vertically extending portion and laterally surrounding the annular semiconductor structure 160. In one embodiment, the semiconductor material layer 14 does not contact and is laterally spaced by a laterally-protruding portion of the memory film 50 from each of the annular semiconductor structures 160.

Referring to FIG. 23F, the processing steps described with reference to FIG. 8F can be performed to form a semiconductor channel material layer 60L and dielectric cores 62.

Referring to FIG. 23G, the processing steps described with reference to FIG. 8G can be performed to form the drain regions 63 and the vertical semiconductor channels 60. In one embodiment, each vertical semiconductor channel 60 comprises a contoured bottom surface including opposing concave surfaces that contact the respective opposing convex surfaces of a semiconductor core structure 161. A p-n junction can be formed at each interface between a semiconductor core structure 161 and a vertical semiconductor channel 60.

Subsequently, the processing steps described with reference to FIGS. 10A-17 can be performed to replace the sacrificial material layers 42 with the electrically conductive layers 46, to form the memory-side metal interconnect structures 960, to bond the logic die 700 to a memory die 900, and to remove the carrier substrate 9 or to thin the backside portion of the carrier substrate 9 to form a thinned carrier substrate 9′.

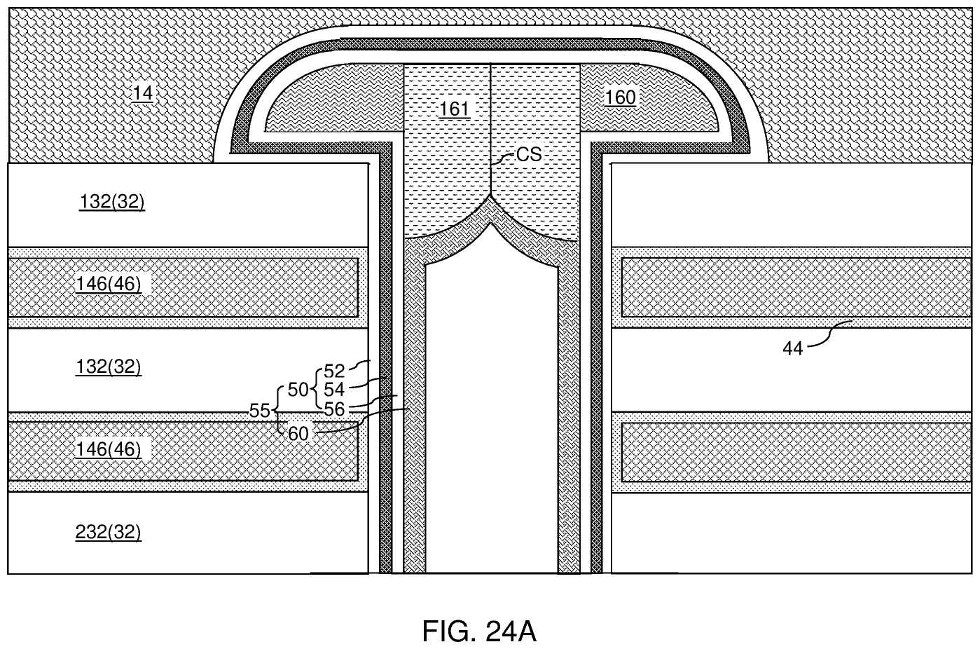

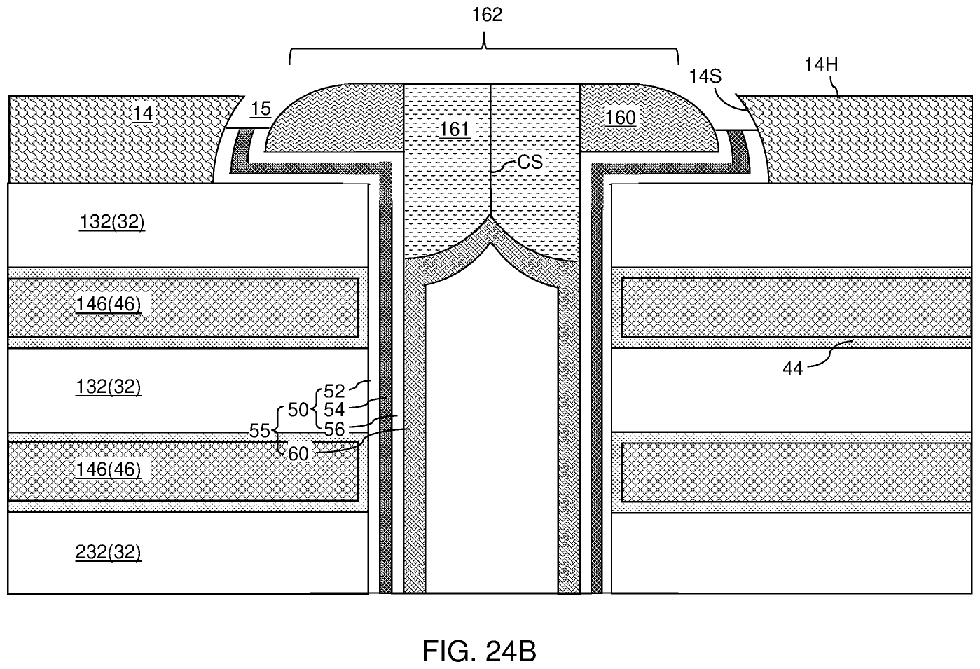

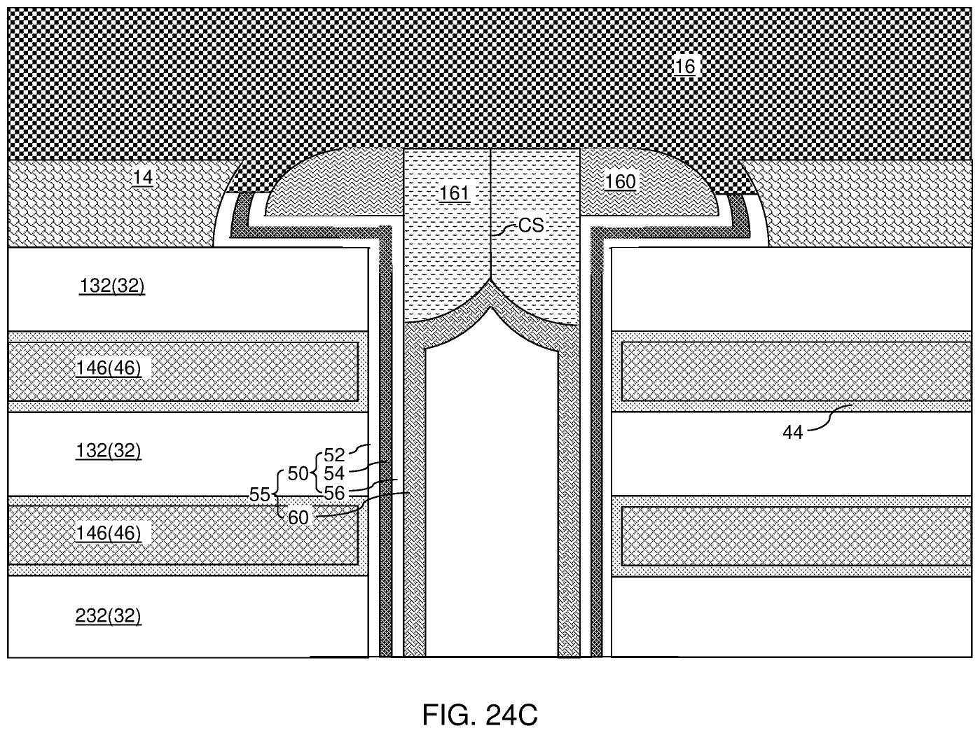

FIGS. 24A-24C are sequential vertical cross-sectional views of a region of the second exemplary structure during removal of the carrier substrate 9, the buried insulating layer 12, and bottom portions of the semiconductor material layer 14 and memory film 50, and formation of a source layer 16 according to the second embodiment of the present disclosure.

Referring to FIG. 24A, if a thinned carrier substrate 9′ remains, then a first etch process can be performed to remove the thinned carrier substrate 9′ selective to the material of the buried insulating layer 12. The backside surface (i.e., the distal surface) of the semiconductor material layer 14 can be physically exposed.

Referring to FIG. 24B, an etch process can be performed to remove a backside surface portion of the semiconductor material layer 14 and to physically expose a bottom surface of each memory film 50. The etch process may comprise an isotropic etch process or an anisotropic etch process. A sequence of etch processes may be performed to sequentially etch the various layers of the memory film 50. For example, physically exposed portions of the blocking dielectric layer 52, the memory material layer 54, and the optional dielectric liner 56 of each memory film 50 can be sequentially etched. The terminal etch step of the sequence of etch processes can be selective to the materials of the semiconductor cap structure (160, 161). Bottom surfaces (i.e., backside surfaces) 162 of the semiconductor cap structures (160, 161) can be physically exposed after the sequence of etch processes.

Referring to FIG. 24C, the processing steps described with reference to FIGS. 19. 20A, and 20B can be performed to form and pattern a source layer 16, a backside insulating layer 34, and at least one optional source contact structure (36, 38).

In summary, the source layer 16 contacts bottom surfaces 162 of the semiconductor core structures 161 and the annular semiconductor structures 160. In one embodiment, the source layer 16 comprises an electrically conductive metal or metallic material. In one embodiment, the source layer 16 contacts a horizontal backside surface 14H of the semiconductor material layer 14 and a surface segment of a inwardly curved sidewall 14S of each opening 15 in the semiconductor material layer 14.

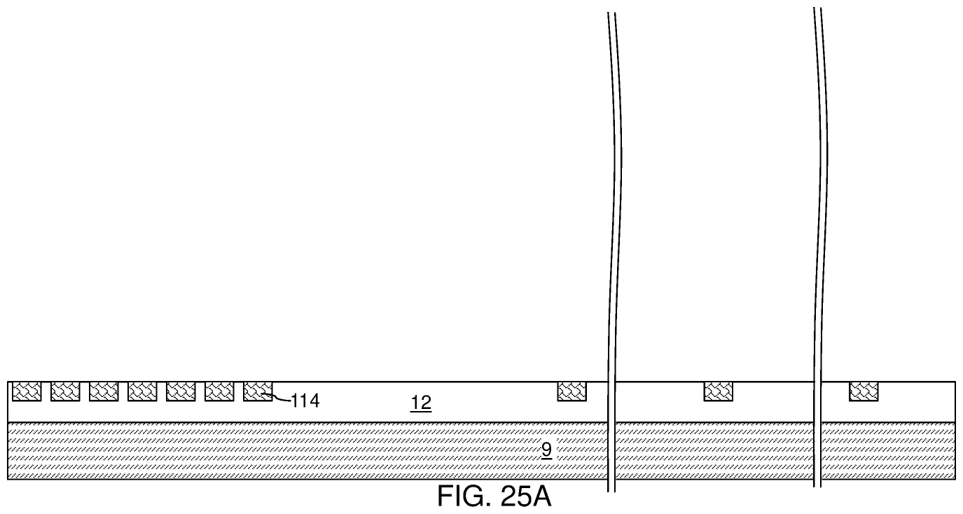

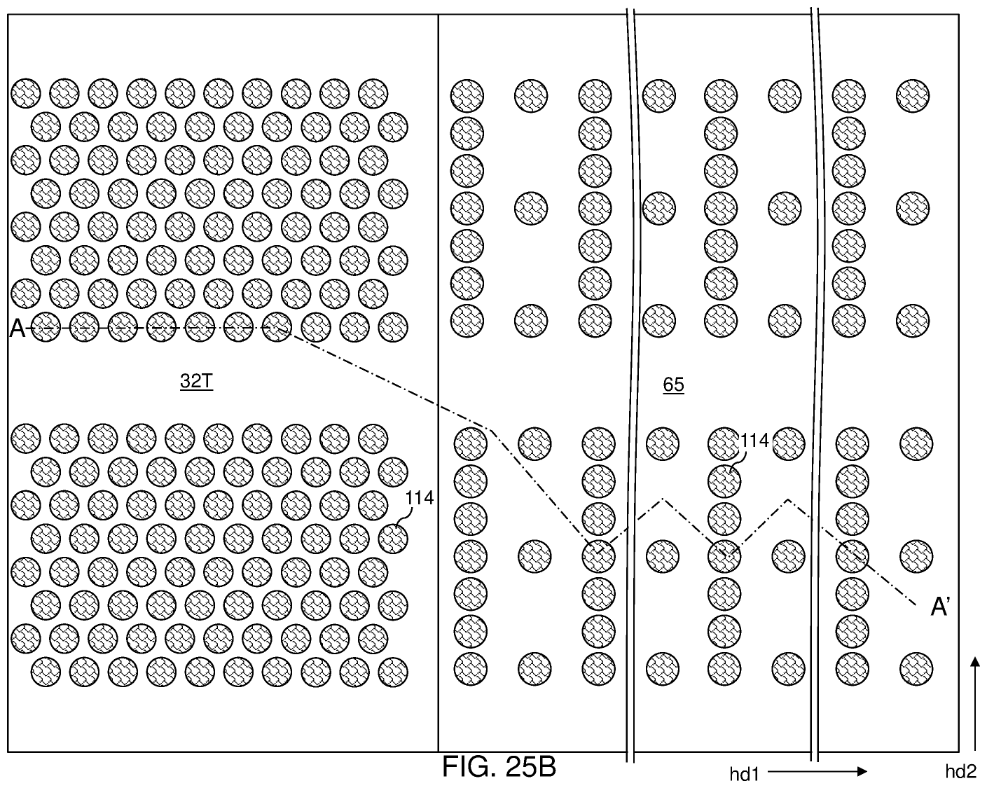

Referring to FIGS. 25A and 25B, a third exemplary structure according to a third embodiment of the present disclosure is illustrated. The third exemplary structure comprises the carrier substrate 9, which may be the same as the carrier substrate 9 in the first or second exemplary structure, and the buried insulating layer 12 located above the carrier substrate 9. The buried insulating layer 12 comprises an insulating material such as silicon oxide, and has a thickness in a range from 80 nm to 400 nm, such as from 120 nm to 300 nm, although lesser and greater thicknesses may also be employed.

A photoresist layer (not shown) can be applied over the top surface of the buried insulating layer 12, and can be lithographically patterned in the same pattern as the pattern of the first-tier memory openings 149 and the first-tier support openings 119 with a modification in the areas of each opening in the photoresist layer. Specifically, the area of each opening in the photoresist layer may be larger than the area of a respective first-tier memory opening 149 or a respective first-tier support opening 119 to be subsequently formed in the same area. In one embodiment, each openings in the photoresist layer may have a periphery that is laterally offset outward from the periphery of a respective first-tier memory opening 149 or a respective first-tier support opening 119 to be subsequently formed in an overlapping area. According to an aspect of the present disclosure, the size of each opening in the photoresist layer can be selected such that neighboring pairs of openings do not merge with each other.

An anisotropic etch process can be performed to etch upper portions of the buried insulating layer 12 that are not masked by the photoresist layer. Recess cavities are formed in volumes from which the material of the buried insulating layer 12 is etched. The depth of the recess cavity may be on the order of the thickness of the semiconductor material layer 14 described above, and may be in a range from 30 nm to 300 nm, such as from 50 nm to 200 nm, although lesser and greater thicknesses may also be employed. The patterned photoresist layer can be subsequently removed, for example, by ashing.

A sacrificial fill material, such as amorphous silicon, polysilicon, a carbon-based material (such as amorphous carbon or diamond-like carbon (DLC)), a high-etch-rate silicate glass (such as borosilicate glass or organosilicate glass), or a polymer material is deposited in the recess cavities. Excess portions of the sacrificial fill material can be removed from above the horizontal plane including the top surface of the buried insulating layer 12. Remaining portions of the sacrificial fill material in the recess cavities constitute sacrificial plate structures 114. The sacrificial plate structures 114 are embedded in the buried insulating layer 12.

Referring to FIG. 26, a first-tier alternating stack (132, 142) can be formed in the manner described with reference to FIG. 1. The processing steps described with reference to FIGS. 2 and 3 can be performed to form a first stepped dielectric material portion 165, first-tier memory openings 149, and first-tier support openings 119. In the third exemplary structure, the chemistry of the anisotropic etch process that forms the first-tier memory openings 149 and the first-tier support openings 119 can be modified to be selective to the material of the sacrificial plate structures 114. In this case, the sacrificial plate structures 114 may function as etch stop structures for the anisotropic etch process that forms the first-tier memory openings 149 and the first-tier support openings 119. Bottom surfaces of the first-tier memory openings 149 and the first-tier support openings 119 may comprise recessed top surfaces of the sacrificial plate structures 114.

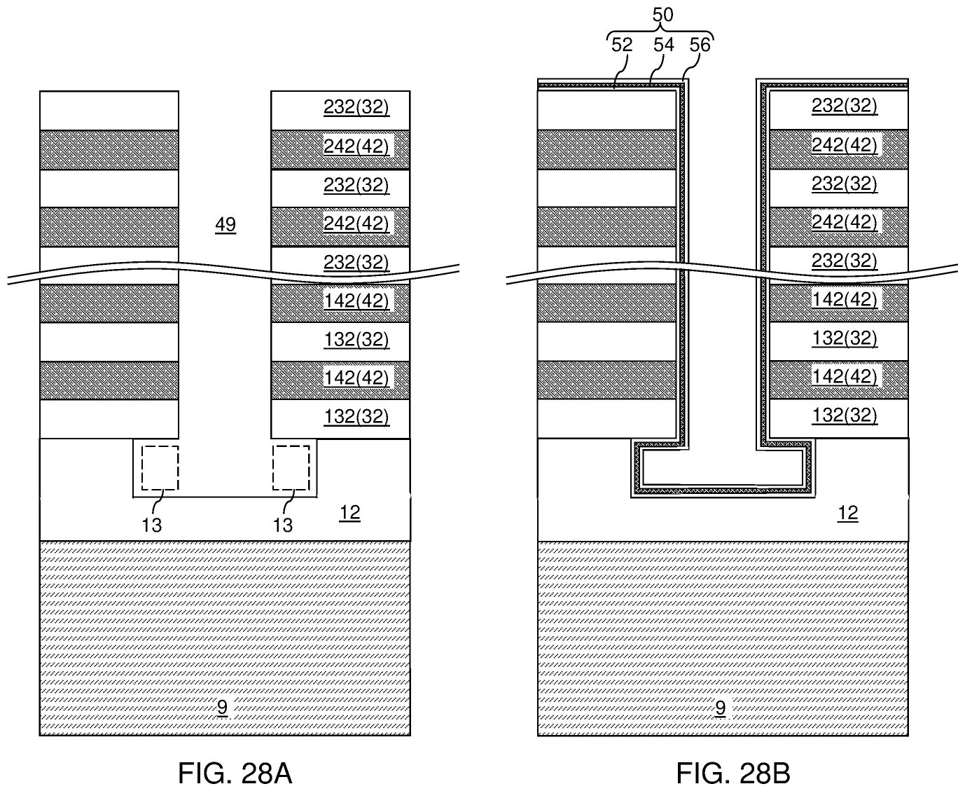

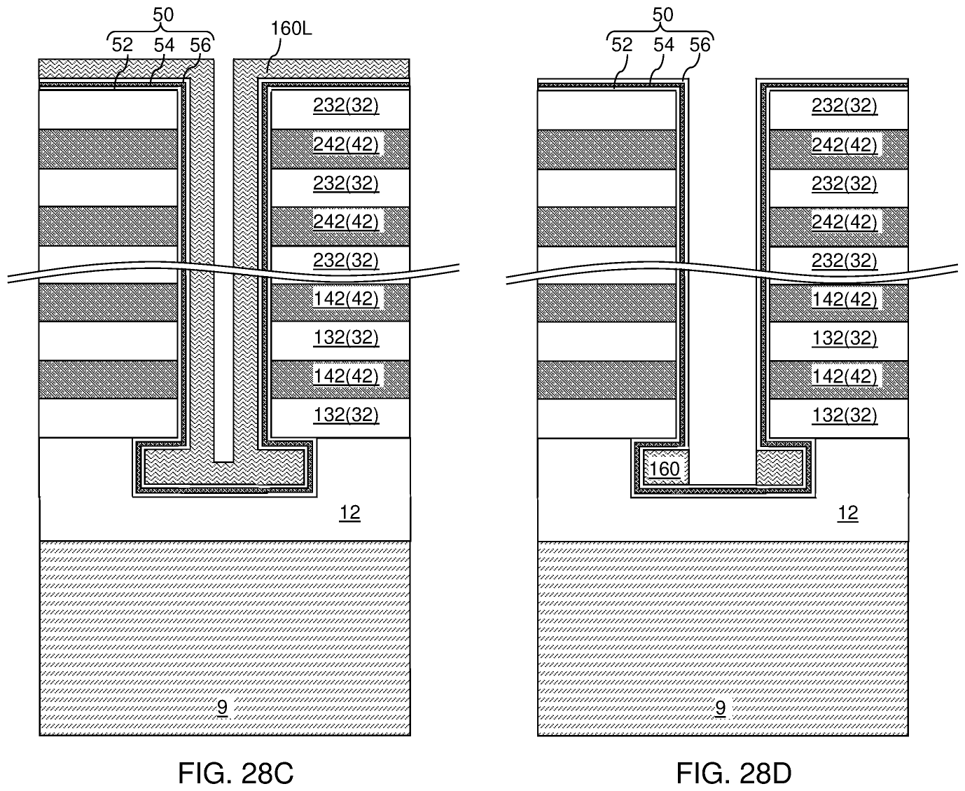

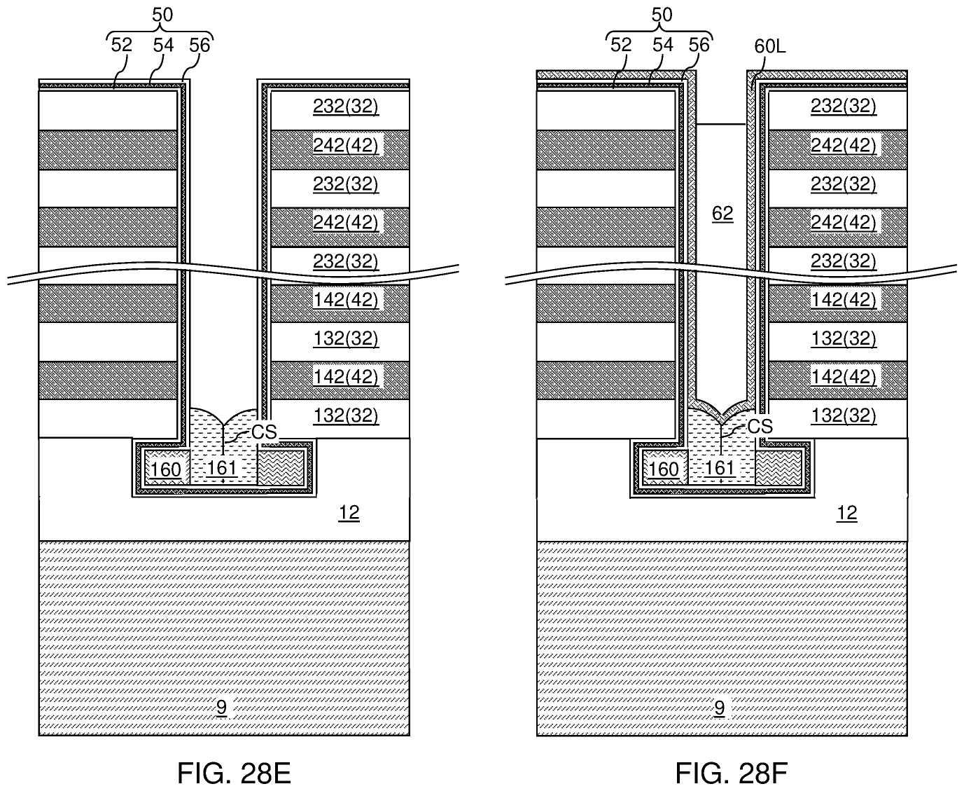

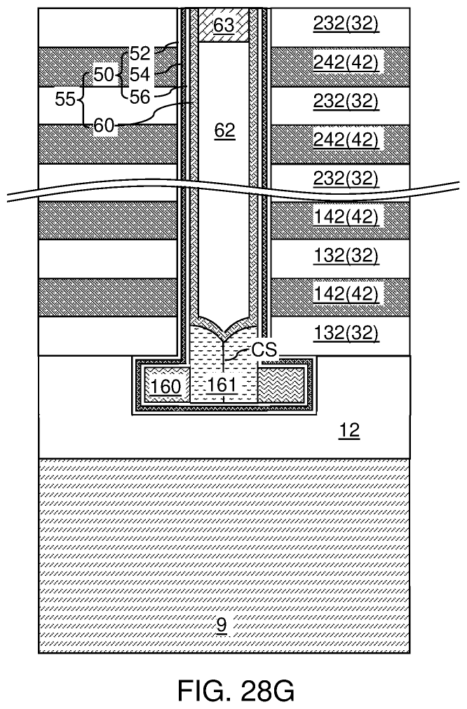

FIGS. 28A-28G are sequential vertical cross-sectional views of a memory opening 49 during formation of a memory opening fill structure 58 in the third exemplary structure according to the third embodiment of the present disclosure.

Referring to FIG. 28A, a selective isotropic etch process or an ashing process can be performed to remove the sacrificial plate structures 114 selective to the materials of the first-tier alternating stack (132, 142) and the buried insulating layer 12. For example, if the sacrificial plate structures 114 comprise amorphous silicon, then a selective silicon etch process may be used. If the sacrificial plate structures 114 comprise a carbon material, then the ashing process may be used. The memory openings 49 can be vertically extended downward to the recessed horizontal surfaces of the recess cavities in buried insulating layer 12. Further, annular cavities 13 can be formed around each bottom portion of the memory openings 49 between the bottom surface of the recess cavities in buried insulating layer 12 and the bottom of the first-tier alternating stack (132, 142).

Referring to FIG. 28B, the processing steps described with reference to FIG. 8B can be performed to form a memory film 50. The memory film 50 can be conformally formed, and thus, may have a uniform thickness throughout.

Referring to FIG. 28C, the processing steps described with reference to FIG. 8C can be performed to form a semiconductor fill material layer 160L.

Referring to FIG. 28D, the processing steps described with reference to FIG. 8D can be performed to form an annular semiconductor structure 160 within each annular cavity 13. In one embodiment, each annular semiconductor structure 160 may have a respective inner cylindrical sidewall that is vertically coincident with an inner cylindrical sidewall of a respective overlying portion of the memory film 50.

Referring to FIG. 28E, the processing steps described with reference to FIG. 8E can be performed to form a semiconductor core structure 161 on an inner cylindrical sidewall of each annular semiconductor structure 160. In the third exemplary structure, the memory openings 49 do not extend below the bottom surface of the buried insulating layer 12. As such, the bottom surface of each semiconductor core structure 161 may contact a horizontal top surface of a respective horizontally-extending portion of the memory film 50 that underlies the cavity within a respective memory opening 49.

In one embodiment, the semiconductor core structure 161 comprises a center seam CS that vertically extends from a center of a top surface thereof to a center of a bottom surface thereof. In one embodiment, the semiconductor core structure 161 comprises a contoured top surface having a periphery that is raised above a center point of the contoured top surface. In one embodiment, the contoured top surface of the semiconductor core structure 161 comprises opposing convex surfaces. In one embodiment, each semiconductor core structure 161 comprises a horizontal bottom surface located within a same horizontal plane as a horizontally-extending portion of a bottom surface of a respective annular semiconductor structure 160.

The buried insulating layer 12 may laterally surround and may embed each annular semiconductor structure 160. In one embodiment, the memory film 50 comprises a vertically-extending portion that vertically extends through the alternating stack (32, 42), and a laterally-protruding portion that is adjoined to a bottom end of the vertically-extending portion and laterally protruding outward from the bottom end of the vertically extending portion and laterally surrounding the annular semiconductor structure 160. In one embodiment, the buried insulating layer 12 does not contact and is laterally spaced by a laterally-protruding portion of the memory film 50 from each of the annular semiconductor structures 160.

Referring to FIG. 28F, the processing steps described with reference to FIG. 8F can be performed to form a semiconductor channel material layer 60L and dielectric cores 62.

Referring to FIG. 28G, the processing steps described with reference to FIG. 8G can be performed to form drain regions 63 and vertical semiconductor channels 60. In one embodiment, each vertical semiconductor channel 60 comprises a contoured bottom surface which includes opposing concave surfaces that contact the respective opposing convex surfaces of a semiconductor core structure 161. A p-n junction can be formed at each interface between a semiconductor core structure 161 and a vertical semiconductor channel 60.

Subsequently, the processing steps described with reference to FIGS. 10A-17 can be performed to replace the sacrificial material layers 42 with electrically conductive layers 46, to form memory-side metal interconnect structures 960, to bond a logic die 700 to a memory die 900, and to remove the carrier substrate 9 or to thin the backside portion of the carrier substrate 9 to form a thinned carrier substrate 9′.

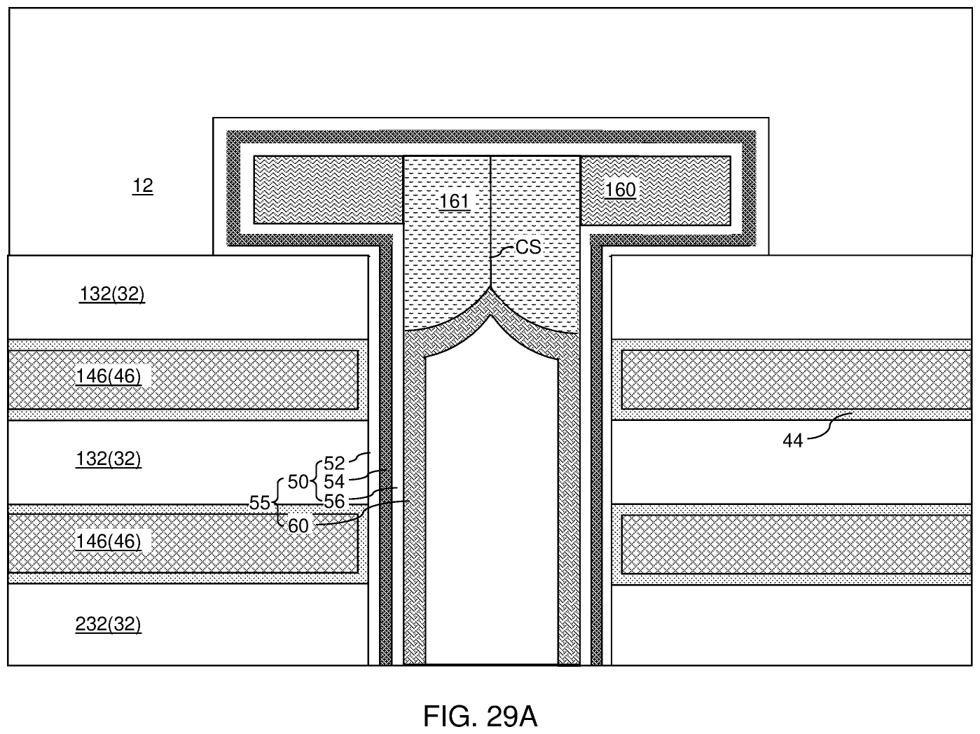

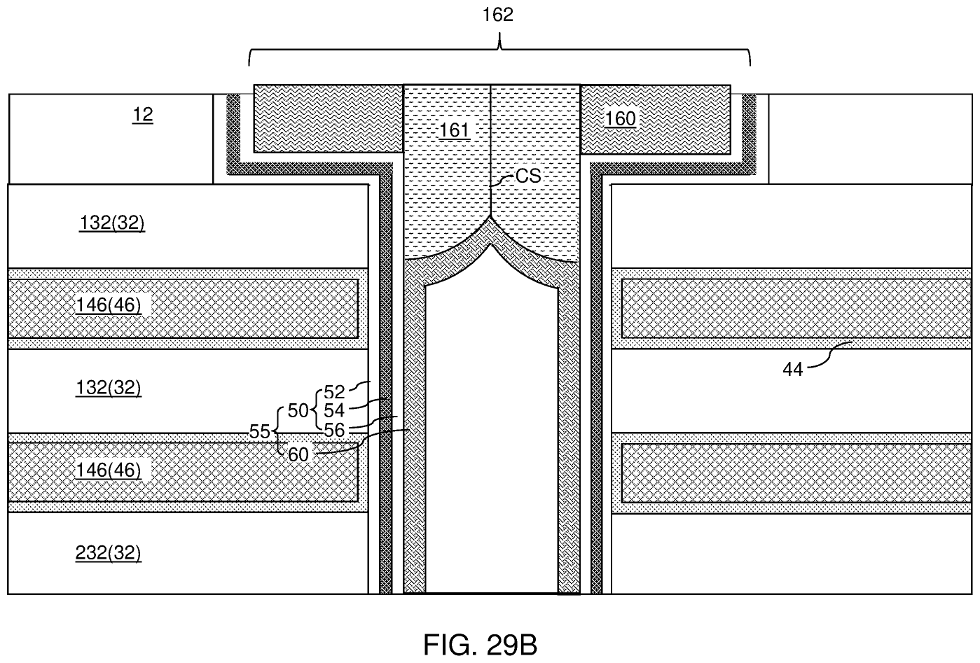

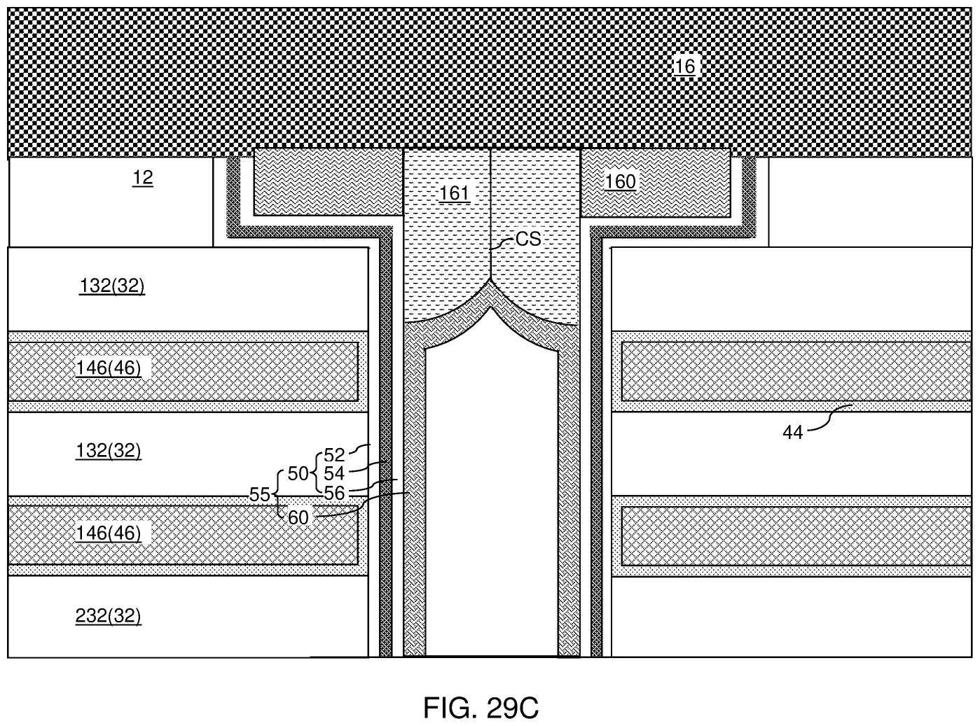

FIGS. 29A-29C are sequential vertical cross-sectional views of a region of the third exemplary structure during removal of the carrier substrate 9 and bottom portions of the buried insulating layer 12 and memory openings 49, and formation of a source layer 16 according to the third embodiment of the present disclosure.

Referring to FIG. 29A, if the thinned carrier substrate 9′ is present, then a first etch process can be performed to etch the material of the thinned carrier substrate 9′ selective to the material of the buried insulating layer 12.

Referring to FIG. 29B, a second etch process can be performed to remove a backside surface portion of the buried insulating layer 12 and to physically expose a bottom surface of each memory film 50. The etch process may comprise an isotropic etch process or an anisotropic etch process. For example, a wet etch process employing dilute hydrofluoric acid may be employed to remove the backside surface portion of the buried insulating layer 12. A sequence of etch processes may be performed to sequentially etch the various layers of the memory film 50. For example, physically exposed portions of the blocking dielectric layer 52, the memory material layer 54, and the optional dielectric liner 56 of each memory film 50 can be sequentially etched. The terminal etch step of the sequence of etch processes can be selective to the materials of the semiconductor cap structure (160, 161). Planar bottom surfaces (i.e., backside surfaces) 162 of the semiconductor cap structures (160, 161) can be physically exposed after the sequence of etch processes.

Referring to FIG. 29C, the processing steps described with reference to FIG. 19 can be performed to form and pattern a source layer 16. Generally, the source layer 16 contacts the planar bottom surfaces 162 of the semiconductor core structures 161 and the annular semiconductor structures 160. In one embodiment, the source layer 16 comprises a metallic material. In the third embodiment, the semiconductor material layer 14 may be omitted.

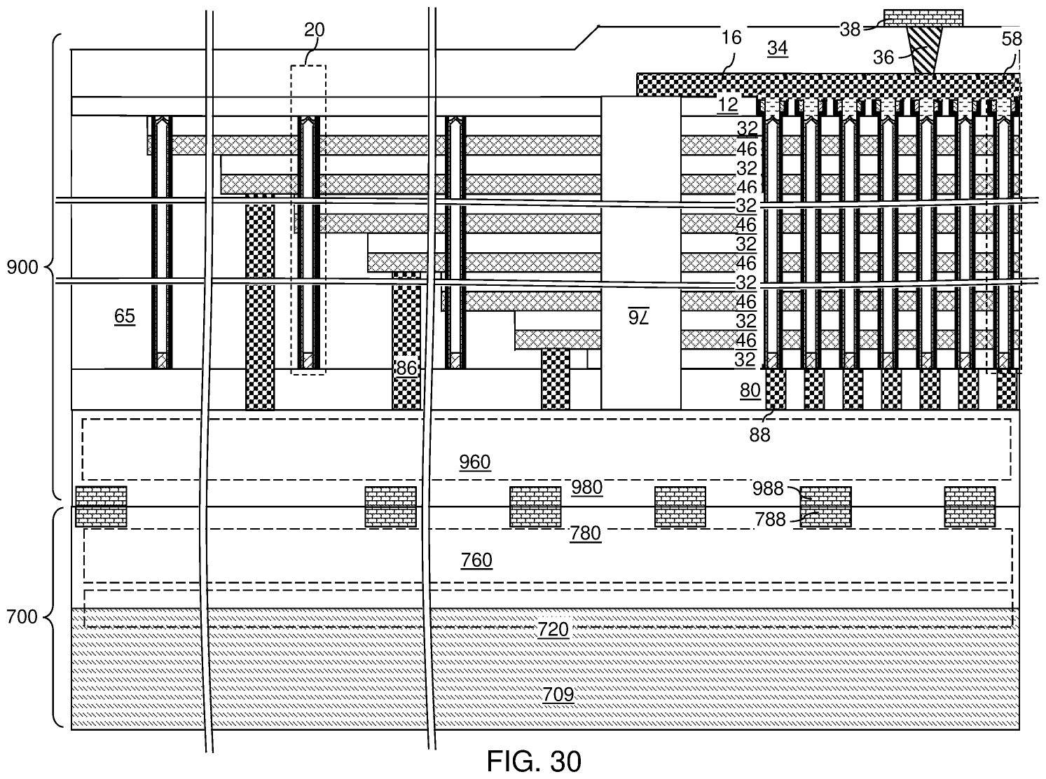

Referring to FIG. 30, the processing steps described with reference to FIGS. 20A and 20B can be performed to form a backside insulating layer 34, and optionally at least one source contact structure (36, 38).

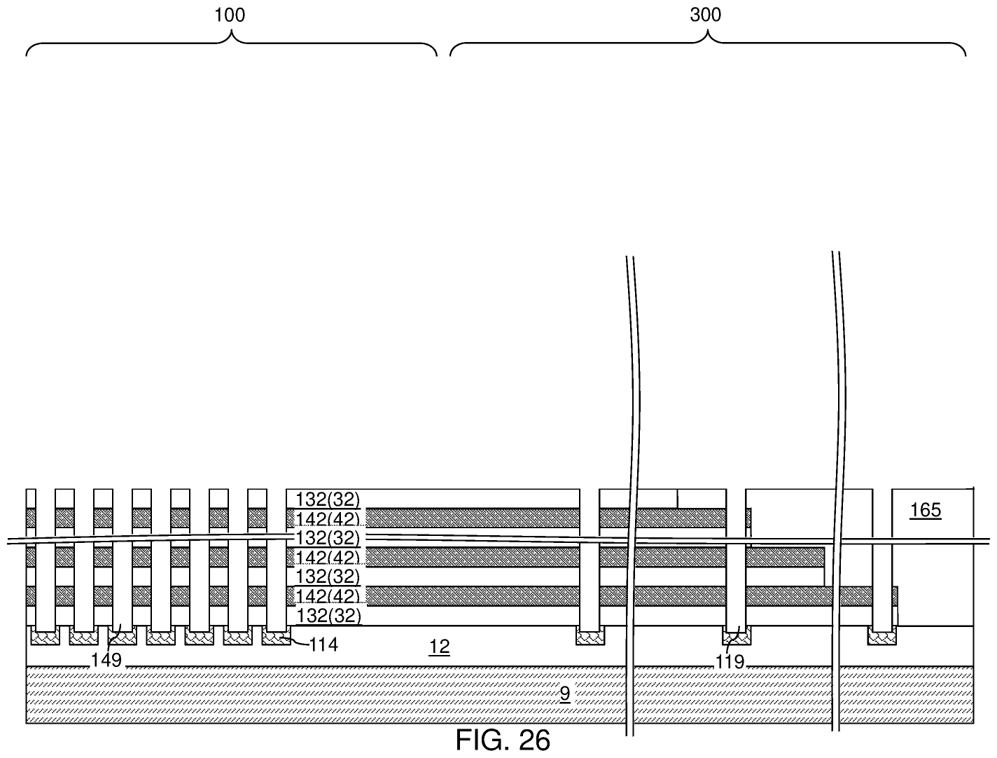

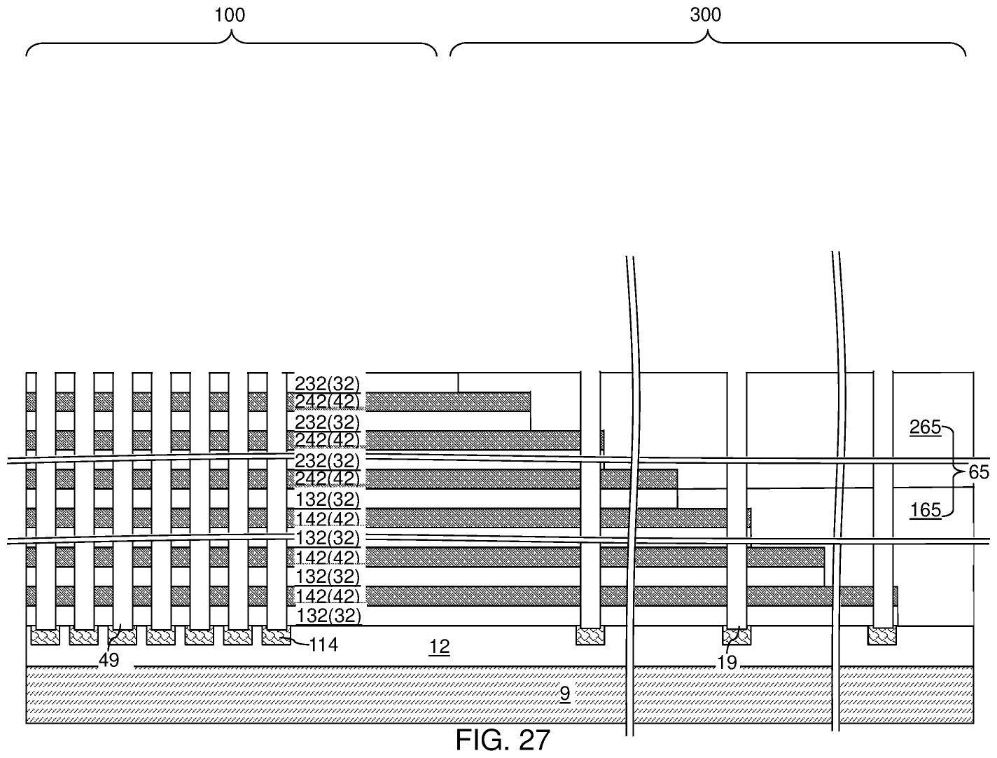

Referring to FIGS. 1-30 and according to various embodiments of the present disclosure, a semiconductor structure comprises: an alternating stack of insulating layers 32 and electrically conductive layers 46; a memory opening 49 vertically extending through the alternating stack (32, 46); a memory opening fill structure 58 located in the memory opening 49 and comprising a memory film 50, a vertical semiconductor channel 60, and a semiconductor cap structure that includes a semiconductor core structure 161 contacting a bottom end of the vertical semiconductor channel 60 and an annular semiconductor structure 160 laterally surrounding the semiconductor core structure 161 and having a lesser vertical extent than the semiconductor core structure 161; and a source layer 16 contacting a bottom surface of the semiconductor core structure 161.

In the embodiments of FIGS. 20B, 24C, and 29C, the source layer 16 also contacts a bottom the annular semiconductor structure 160. However, in the alternative embodiment of FIG. 20C, the source layer 16 does not contact the annular semiconductor structure 160.

In one embodiment, the semiconductor core structure 161 comprises a center seam CS that vertically extends from a center of a top surface thereof to a center of a bottom surface thereof. In one embodiment, the semiconductor core structure 161 comprises a contoured top surface having a periphery that is raised above a center point of the contoured top surface. In one embodiment, the contoured top surface of the semiconductor core structure 161 comprises opposing (e.g., facing each other) convex surfaces; and the vertical semiconductor channel 60 comprises a contoured bottom surface comprises opposing (e.g., facing each other) concave surfaces that contact the respective opposing convex surfaces of the semiconductor core structure 161.

In one embodiment, the semiconductor structure comprises a semiconductor material layer 14 interposed between the alternating stack (32, 46) and the source layer 16 and laterally surrounding the annular semiconductor structure 160. In one embodiment, the memory film 50 comprises: a vertically-extending portion that vertically extends through the alternating stack (32, 46); and a laterally-protruding portion that is adjoined to a bottom end of the vertically-extending portion and laterally protruding outward from the bottom end of the vertically extending portion and laterally surrounding the annular semiconductor structure 160. In one embodiment, the semiconductor material layer 14 does not contact, and is laterally spaced by the laterally-protruding portion of the memory film 50 from, the annular semiconductor structure 160. In one embodiment, the source layer 16 contacts a horizontal backside surface 14H of the semiconductor material layer 14 and optionally contacts a vertical or curved surface segment (14V, 14S) of a sidewall of an opening 15 in the semiconductor material layer 14.

In one embodiment, the semiconductor structure comprises a buried insulating layer 12 located between the alternating stack (32, 46) and the source layer 16 and laterally surrounding the annular semiconductor structure 160.

In one embodiment, the semiconductor core structure 161 protrudes downward below a horizontal plane including a bottom surface of the annular semiconductor structure 160. In one embodiment, the semiconductor core structure 161 comprises a contoured bottom surface having a periphery that is located below a center point of the contoured bottom surface.

In one embodiment, the semiconductor core structure 161 comprises a horizontal bottom surface located within a same horizontal plane as a horizontally-extending portion of a bottom surface of the annular semiconductor structure 160. In one embodiment, the bottom surface of the annular semiconductor structure 160 comprises a tapered convex annular surface adjoined to the horizontally-extending portion of the bottom surface of the annular semiconductor structure 160. In one embodiment, the source layer 16 comprises a metallic material.

The various embodiments of the present disclosure can be employed to provide enhanced control for the location of p-n junctions between vertical semiconductor channels 60 and a source structure (160, 161, 16). The source structure (160, 161, 16) includes semiconductor cap structure (160, 161) and a source layer 16 which may be a metallic source layer which forms a low resistance ohmic contact with the semiconductor cap structure. The embodiment methods have a reduced number of steps, do not require an additional step of removing a bottom of the semiconductor channel material layer 60L through the memory opening 49, and do not require a laser anneal to activate dopants in a semiconductor source structure, which may negatively affect the copper interconnects and bonding pads at the interface between the logic die 700 and the memory die 900. The location of the p-n junctions can be adjusted with accuracy by controlling the duration of the selective semiconductor deposition process that forms the semiconductor core structures 161, and by controlling the thermal budget after formation of the p-n junctions.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A semiconductor structure, comprising:
an alternating stack of insulating layers and electrically conductive layers;
a memory opening vertically extending through the alternating stack;
a memory opening fill structure located in the memory opening and comprising a memory film, a vertical semiconductor channel, and a semiconductor cap structure comprising a semiconductor core structure contacting a bottom end of the vertical semiconductor channel and an annular semiconductor structure laterally surrounding the semiconductor core structure and having a lesser vertical extent than the semiconductor core structure; and
a source layer contacting a bottom surface of the semiconductor core structure.

2. The semiconductor structure of claim 1, wherein the source layer further contacts a bottom surface of the annular semiconductor structure.

3. The semiconductor structure of claim 1, wherein:
the semiconductor core structure comprises a center seam that vertically extends from a center of a top surface thereof to a center of a bottom surface thereof; and
the semiconductor core structure comprises a contoured top surface having a periphery that is raised above a center point of the contoured top surface.

4. The semiconductor structure of claim 3, wherein:
the contoured top surface of the semiconductor core structure comprises opposing convex surfaces; and
the vertical semiconductor channel comprises a contoured bottom surface comprising opposing concave surfaces that contact the respective opposing convex surfaces of the semiconductor core structure.

5. The semiconductor structure of claim 1, further comprising a semiconductor material layer located between the alternating stack and the source layer and laterally surrounding the annular semiconductor structure.

6. The semiconductor structure of claim 5, wherein the memory film comprises:
a vertically-extending portion that vertically extends through the alternating stack; and
a laterally-protruding portion that is adjoined to a bottom end of the vertically-extending portion and laterally protruding outward from the bottom end of the vertically extending portion and laterally surrounding the annular semiconductor structure.

7. The semiconductor structure of claim 6, wherein the semiconductor material layer does not contact and is laterally spaced by the laterally-protruding portion of the memory film from the annular semiconductor structure.

8. The semiconductor structure of claim 5, wherein the source layer contacts a horizontal backside surface of the semiconductor material layer.

9. The semiconductor structure of claim 1, further comprising an insulating material layer located between the alternating stack and the source layer and laterally surrounding the annular semiconductor structure.

10. The semiconductor structure of claim 1, wherein the semiconductor core structure protrudes downward below a horizontal plane including a bottom surface of the annular semiconductor structure.

11. The semiconductor structure of claim 10, wherein the semiconductor core structure comprises a contoured bottom surface having a periphery that is located below a center point of the contoured bottom surface.

12. The semiconductor structure of claim 1, wherein the semiconductor core structure comprises a horizontal bottom surface located within a same horizontal plane as a horizontally-extending portion of a bottom surface of the annular semiconductor structure.

13. The semiconductor structure of claim 12, wherein the bottom surface of the annular semiconductor structure comprises a tapered convex annular surface adjoined to the horizontally-extending portion of the bottom surface of the annular semiconductor structure.

14. The semiconductor structure of claim 1, wherein the source layer comprises a metallic material.

15. A method of forming a semiconductor structure, comprising:
forming a material layer over a carrier substrate;
forming an alternating stack of insulating layers and spacer material layers over the material layer, wherein the spacer material layers are formed as, or are subsequently replaced with, electrically conductive layers;
forming a memory opening through the alternating stack and into the material layer;
forming an annular cavity around a bottom portion of the memory opening at a level of the material layer;
forming a memory film on exposed surfaces of the memory opening and the annular cavity;
forming an annular semiconductor structure within a remaining volume of the annular cavity;
forming a semiconductor core structure on an inner sidewall of the annular semiconductor structure; and
forming a vertical semiconductor channel on a top surface of the semiconductor core structure.

16. The method of claim 15, further comprising:
removing the carrier substrate;
exposing a surface of the semiconductor core structure after removal of the carrier substrate; and
forming a source layer on the exposed surface of the semiconductor core structure.

17. The method of claim 15, wherein the step of forming the annular semiconductor structure comprises:
conformally depositing a semiconductor fill material in the annular cavity and in a peripheral portion of the memory opening; and
removing a portion of the semiconductor fill material from inside the memory opening, wherein a remaining portion of the deposited semiconductor fill material is the annular cavity constitutes the annular semiconductor structure.

18. The method of claim 15, wherein:
the material layer comprises a semiconductor material layer;
the memory opening is formed through the semiconductor material layer; and
the annular cavity is formed by laterally recessing an annular portion of the semiconductor material layer around the memory opening.

19. The method of claim 15, wherein:
the material layer comprises a semiconductor material layer;
a bottom surface of the memory opening is formed on a top surface of the semiconductor material layer or within the semiconductor material layer; and
the annular cavity is formed by isotropically recessing a portion of the semiconductor material layer that is proximal to the memory opening.

20. The method of claim 15, further comprising:
forming a sacrificial plate structure within the material layer, wherein the material layer comprises insulating material layer; and
removing the sacrificial plate structure through the memory opening, wherein a portion of a volume from which the sacrificial plate structure is removed and does not have an areal overlap with the memory opening in a plan view comprises the annular cavity.
